(19) United States
(12) Patent Application Publication
(10) Pub. No.: US 2026/0282688 A1
(43) Pub. Date: Sep. 17, 2026

(54) LIGHT-EMITTING DEVICE, DISPLAY DEVICE, PHOTOELECTRIC CONVERSION DEVICE, ELECTRONIC DEVICE, LIGHTING DEVICE, AND MOBILE OBJECT

(71) Applicant: CANON KABUSHIKI KAISHA, Tokyo (JP)

(72) Inventor: TASUKU KANEDA, Kanagawa (JP)

(21) Appl. No.: 19/680,754

(22) Filed: May 18, 2026

Related U.S. Application Data
(63) Continuation of application No. PCT/JP2024/039121, filed on Nov. 1, 2024.

(30) Foreign Application Priority Data
Nov. 21, 2023 (JP) 2023-197590
Aug. 23, 2024 (JP) 2024-143349

(51) Int. Cl. H10K 59/131; H10K 59/124; H10K 59/80

(52) U.S. Cl. CPC H10K 59/131; H10K 59/124; H10K 59/878

(57) ABSTRACT

A light-emitting device includes a substrate; an interlayer insulating layer located above the substrate and having a conductive member embedded therein, a laminated structure located above the interlayer insulating layer and constituted by metal layers laminated on each other, and a light-emitting element located above the laminated structure. The metal layers include a first metal layer including a portion in contact with the conductive member and a second metal layer located above the first metal layer. The second metal layer has a reflective surface that reflects light from the light-emitting element toward the light-emitting element. A material of the first metal layer has a resistivity higher than that of a material of the second metal layer. The material of the second metal layer has a reflectivity higher than that of the material of the first metal layer.

### CROSS-REFERENCE TO RELATED APPLICATIONS

This application is a Continuation of International Patent Application No. PCT/JP2024/039121, filed Nov. 1, 2024, which claims the benefit of Japanese Patent Application No. 2023-197590 filed on Nov. 21, 2023, and Japanese Patent Application No. 2024-143349 filed on Aug. 23, 2024, all of which are hereby incorporated by reference herein in their entirety.

### BACKGROUND

### Field of the Technology

The present disclosure relates to a light-emitting device, a display device, a photoelectric conversion device, an electronic device, a lighting device, and a mobile object.

### Description of the Related Art

Head-mounted displays and thin displays using organic electroluminescence (EL) elements, which are characterized by their thinness, lightness, and low power consumption, have been put to practical use. Japanese Patent Laid-Open No. 2021-072282 proposes an optical resonance structure in which a reflective portion is disposed below an organic EL element. The distance between a lower electrode of the organic EL element and the reflective portion varies depending on the color emitted by the pixel, and light emission with enhanced luminance is obtained at the resonance wavelength for each color. Japanese Patent Laid-Open No. 2016-122612 proposes a structure that reduces the terminal resistance of the anode electrode when an optical resonance structure is formed in each pixel. The reflective portion used to provide the optical resonance structure may function also as part of the wiring. The required characteristics may differ between the reflection function and the wiring function.

### SUMMARY

Some aspects of the present disclosure provide a reflective layer that achieves both a reflective function and a wiring function. According to some embodiments, a light-emitting device comprising: a substrate; an interlayer insulating layer that is located above the substrate and has a conductive member embedded therein; a laminated structure that is located above the interlayer insulating layer and is constituted by a plurality of metal layers laminated on each other; and a light-emitting element located above the laminated structure, wherein the plurality of metal layers include: a first metal layer including a portion in contact with the conductive member; and a second metal layer located above the first metal layer, the second metal layer has a reflective surface that reflects light from the light-emitting element toward the light-emitting element, a material of the first metal layer has a resistivity higher than that of a material of the second metal layer, and the material of the second metal layer has a reflectivity higher than that of the material of the first metal layer, is provided.

Features of the present disclosure will become apparent from the following description of embodiments with reference to the attached drawings.

### BRIEF DESCRIPTION OF THE DRAWINGS

FIG. 1 is a cross-sectional view illustrating a configuration of a light-emitting device according to a first embodiment.

FIG. 2 is a plan view illustrating a shape of a reflective layer according to the first embodiment.

FIG. 3A is a cross-sectional view illustrating a method for manufacturing the light-emitting device according to the first embodiment.

FIG. 3B is a cross-sectional view illustrating a method for manufacturing the light-emitting device according to the first embodiment.

FIG. 3C is a cross-sectional view illustrating a method for manufacturing the light-emitting device according to the first embodiment.

FIG. 3D is a cross-sectional view illustrating a method for manufacturing the light-emitting device according to the first embodiment.

FIG. 4A is a cross-sectional view illustrating a method for manufacturing the light-emitting device according to the first embodiment.

FIG. 4B is a cross-sectional view illustrating a method for manufacturing the light-emitting device according to the first embodiment.

FIG. 4C is a cross-sectional view illustrating a method for manufacturing the light-emitting device according to the first embodiment.

FIG. 4D is a cross-sectional view illustrating a method for manufacturing the light-emitting device according to the first embodiment.

FIG. 5 is a cross-sectional view illustrating a configuration of a light-emitting device according to a second embodiment.

FIG. 6 is a cross-sectional view illustrating a configuration of a light-emitting device according to a third embodiment.

FIG. 7 is a cross-sectional view illustrating a configuration of a light-emitting device according to a fourth embodiment.

FIG. 8 is a cross-sectional view illustrating a configuration of a light-emitting device according to a fifth embodiment.

FIG. 9 is a plan view illustrating a shape of a reflective layer according to the fifth embodiment.

FIG. 10 is a cross-sectional view illustrating a configuration of a light-emitting device according to a sixth embodiment.

FIG. 11 is a cross-sectional view illustrating a configuration of a light-emitting device according to a seventh embodiment.

FIG. 12 is a cross-sectional view illustrating a configuration of a light-emitting device according to an eighth embodiment.

FIG. 13 is a cross-sectional view illustrating a configuration of a modified example of the light-emitting device of the eighth embodiment.

FIG. 14 is a cross-sectional view illustrating a configuration of a light-emitting device according to a ninth embodiment.

FIG. 15 is a cross-sectional view illustrating a configuration of a light-emitting device according to a tenth embodiment.

FIG. 16 is a diagram showing an example of a display device using the light-emitting device of the above embodiment.

FIG. 17A is a diagram showing an example of a photoelectric conversion device using the light-emitting device of the above embodiment.

FIG. 17B is a diagram showing an example of an electronic device using the light-emitting device of the above embodiment.

FIG. 18A is a diagram showing an example of a display device using the light-emitting device of the above embodiment.

FIG. 18B is a diagram showing an example of a display device using the light-emitting device of the above embodiment.

FIG. 19A is a diagram showing an example of an illumination device using the light-emitting device of the above embodiment.

FIG. 19B is a diagram showing an example of a mobile object using the light-emitting device of the above embodiment.

FIG. 20A is a diagram showing an example of a wearable device using the light-emitting device of the above embodiment.

FIG. 20B is a diagram showing an example of a wearable device using the light-emitting device of the above embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

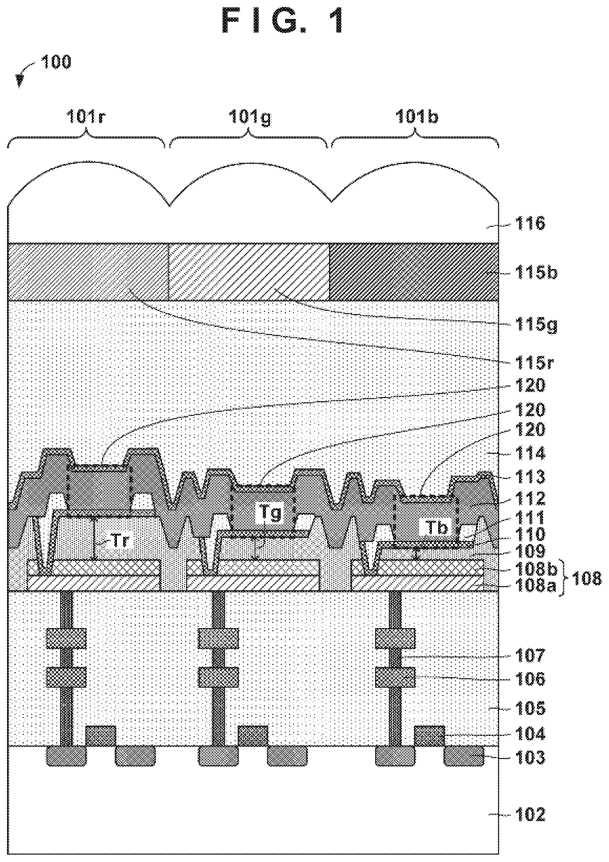

A cross-sectional structure of a light-emitting device 100 according to a first embodiment will be described with reference to FIG. 1. In FIG. 1, the light-emitting device 100 is disposed in an orientation of emitting light upward in the drawing. In the following description, the positional relationships (particularly the vertical relationships) between the constituent elements in this arrangement will be described.

In FIG. 1, attention is given to a portion of the light-emitting device 100 that includes three pixels 101r, 101g, and 101b. The light-emitting device 100 may include three or more pixels. The pixel 101r is a pixel for emitting red light. The pixel 101g is a pixel for emitting green light. The pixel 101b is a pixel for emitting blue light. The light-emitting device 100 having such pixels can display a color image. However, the technology described herein is also applicable to a light-emitting device 100 that emits monochromatic light. The pixels 101r, 101g, and 101b may be collectively referred to as a pixel 101. The description of the pixel 101 may also be applied to any of the pixels 101r, 101g, and 101b.

The pixel 101 includes a light-emitting element 120. The light-emitting element 120 may emit light at a luminance that corresponds to the value of the current flowing through the light-emitting element. In the following example, a case will be described in which the light-emitting element 120 is an organic light-emitting element. However, the technology described herein is also applicable to other types of light-emitting devices, such as light emitting diodes and light emitting transistors.

One or more circuit elements (e.g., transistors) are formed on a semiconductor substrate 102. For example, a plurality of impurity regions 103 are formed in the semiconductor substrate 102. A gate electrode 104 is disposed on the surface of the semiconductor substrate 102 via a gate insulating film. The gate electrode 104 and two impurity regions 103 form a MOS (metal-oxide-semiconductor) transistor. One of the two impurity regions 103 included in the MOS transistor functions as a source, and the other functions as a drain. The MOS transistor may be used to drive the light-emitting element 120 included in the pixel 101. An element isolation region (e.g., STI (Shallow Trench Isolation)) may also be formed in the semiconductor substrate 102.

An interlayer insulating layer 105 is disposed on the semiconductor substrate 102. The interlayer insulating layer 105 (specifically, the lower surface thereof) is in contact with the semiconductor substrate 102 (specifically, the upper surface thereof). One or more wiring layers 106 and a plurality of contact plugs 107 are embedded in the interlayer insulating layer 105. The one or more wiring layers 106 and the plurality of contact plugs 107 are conductive members for transmitting electrical signals or power source voltages.

The plurality of contact plugs 107 may include contact plugs that connect circuit elements (e.g., the impurity regions 103 or the gate electrodes 104) formed in the semiconductor substrate 102 to the wiring layer 106. The plurality of contact plugs 107 may include contact plugs that connect the wiring layers 106 of different layers to each other. The plurality of contact plugs 107 may include contact plugs that connect the wiring layers 106 and a reflective layer 108. The contact plugs 107 may include a tungsten film containing a barrier metal such as Ti/TiN.

The interlayer insulating layer 105 may be a boro-phospho-silicate glass (BPSG) film formed by thermal chemical vapor deposition (CVD) or a silicon oxide film formed by plasma CVD. The wiring layer 106 may include aluminum wiring or copper wiring. In the example of FIG. 1, the light-emitting device 100 has two wiring layers 106. Alternatively, the light-emitting device 100 may have only one wiring layer 106 or three or more wiring layers 106. The plurality of wiring layers 106 may contain both aluminum wiring and copper wiring.

The reflective layer 108 is disposed on the interlayer insulating layer 105. The reflective layer 108 (specifically, the lower surface thereof) is in contact with the interlayer insulating layer 105 (specifically, the upper surface thereof) and the contact plug 107 (specifically, the upper surface thereof). In this way, the reflective layer 108 includes a portion in contact with the contact plug 107. Alternatively, when the wiring layer 106 is formed on the interlayer insulating layer 105, the reflective layer 108 may include a portion in contact with the wiring layer 106. The reflective layer 108 is electrically connected to circuit elements (e.g., transistors) formed on the semiconductor substrate 102 through the wiring layer 106 and the contact plugs 107.

The reflective layer 108 is separated for each pixel 101. Specifically, the reflective layer 108 includes a portion included in the pixel 101r, a portion included in the pixel 101g, and a portion included in the pixel 101b, and these portions are separated from one another.

The reflective layer 108 may have a thickness (e.g., 200 nm or more and 2000 nm or less, or specifically, about 300 nm) that can be used as a pad for the light-emitting device 100. If the reflective layer 108 can be used as a pad for the light-emitting device 100, it is no longer necessary to form a separate wiring layer for the pad, and therefore the cost of the light-emitting device 100 can be reduced.

The reflective layer 108 has a laminated structure constituted by a plurality of metal layers laminated on each other. In the example of FIG. 1, the reflective layer 108 has a laminated structure constituted by two metal layers, namely, a metal layer 108a and a metal layer 108b, which are laminated on each other. The metal layer 108a and the metal layer 108b are in contact with each other. The metal layer 108b is located above top of the metal layer 108a.

The metal layer 108a is the bottom layer of the plurality of metal layers. The metal layer 108a includes a portion in contact with the interlayer insulating layer 105 and a portion in contact with the contact plug 107. The metal layer 108b is the top layer of the plurality of metal layers. The upper surface of the metal layer 108b is in contact with the lower surface of an optical adjustment layer 109. The reflective layer 108 reflects the light emitted from the light-emitting element 120 toward the light-emitting element 120. Specifically, the metal layer 108b included in the reflective layer 108 has a reflective surface that reflects the light from the light-emitting element 120 toward the light-emitting element 120. Both direct light directed from the light-emitting element 120 to the outside of the light-emitting device 100 (upward in FIG. 1) and reflected light reflected by the reflective layer 108 are emitted from the pixel 101.

As described above, the upper surface of the reflective layer 108 reflects light from the light-emitting element 120, and the lower surface of the reflective layer 108 is in contact with a conductive member (e.g., the contact plug 107) embedded in the interlayer insulating layer 105. For this reason, the required properties of the upper and lower surfaces of the reflective layer 108 are different. In view of this, the metal layers 108a and 108b may include materials corresponding to these properties. For example, the material of the metal layer 108a may have a resistivity higher than that of the material of the metal layer 108b. This reduces the contact resistance between the reflective layer 108 and the contact plug 107. The reflectivity of the material of the metal layer 108b may be higher than the reflectivity of the material of the metal layer 108a. This improves the light emission efficiency of the optical resonance structure formed by the reflective layer 108. Specifically, the metal layer 108a may include at least one of titanium, titanium nitride, and a titanium alloy. The metal layer 108b may include at least one of aluminum, an aluminum alloy, copper, a copper alloy, silver, and a silver alloy. The metal layer 108a may be thinner than the metal layer 108b. The thickness of the metal layer 108 b may be 10 nm or more and 100 nm or less. In the light-emitting device 100, the portion of the reflective layer 108 that is in contact with the conductive member (e.g., the contact plug 107) embedded in the interlayer insulating layer 105 is electrically connected to the reflective surface of the reflective layer 108.

Since the metal layer 108a is in contact with the lower surface of the metal layer 108b, the crystal orientation of the metal layer 108b is influenced by the crystal orientation of the metal layer 108a. Influencing the orientation of the metal layer 108b can influence the electromigration and reliability of the wiring provided by the reflective layer 108. By forming the metal layer 108a by laminating, for example, titanium nitride and a titanium film, the influence of the crystal orientation of the metal layer 108b can be reduced. Furthermore, the crystal orientation of the metal layer 108b may be controlled by adjusting the thickness and film-forming temperature of the metal layer 108a. The film-forming temperature of the metal layer 108 a may be, for example, about 250° C.

The optical adjustment layer 109 is disposed on the reflective layer 108. The optical adjustment layer 109 (specifically, the lower surface thereof) is in contact with the reflective layer 108 (specifically, the upper surface thereof). Furthermore, the optical adjustment layer 109 (specifically, the lower surface thereof) also includes a portion in contact with the interlayer insulating layer 105. The optical adjustment layer 109 covers the upper surface of the reflective layer 108. The optical adjustment layer 109 may include a material with high light transmittance, such as SiO, SiN, ITO, or IZO. For this reason, the optical adjustment layer 109 may also be called a light-transmitting layer. The optical adjustment layer 109 may be formed by combining a plurality of materials (e.g., SiO and ITO) in some of the pixels 101 (e.g., the pixel 101r). In addition, the configuration of the optical adjustment layer 109 may differ for each pixel 101. If ITO is combined with the material of the optical adjustment layer 109, the contact resistance between the lower electrode 110 and the reflective layer 108 can be reduced by lowering the resistance of the lower electrode 110.

The thickness of the optical adjustment layer 109 may differ for each pixel 101. For example, the thickness of the optical adjustment layer 109 may be a value corresponding to the resonance wavelength of each pixel 101. In the optical adjustment layer 109, the thickness of the portion included in the pixel 101r is denoted as Tr, the thickness of the portion included in the pixel 101g is denoted as Tg, and the thickness of the portion included in the pixel 101b is denoted as Tb. When the thicknesses Tr, Tg, and Tb of the optical adjustment layer 109 have values corresponding to the resonance wavelengths of red light, green light, and blue light, respectively, the relationship Tr>Tg>Tb can be satisfied.

The lower electrode 110 is disposed on the optical adjustment layer 109. A portion of the lower electrode 110 (specifically, the lower surface thereof) is in contact with the optical adjustment layer 109 (specifically, the upper surface thereof). The light-emitting device 100 has a separate lower electrode 110 for each pixel 101. That is, the lower electrode 110 of one pixel 101 (e.g., the pixel 101r) and the lower electrode 110 of another pixel 101 (e.g., the pixel 101b) are isolated from each other.

A portion of the lower electrode 110 passes through the optical adjustment layer 109 and is in contact with the reflective layer 108. Specifically, in the example of FIG. 1, a portion of the lower electrode 110 further passes through the metal layer 108b and is in contact with the metal layer 108a (specifically, the upper surface thereof). As a result, the distance between the portion of the lower electrode 110 closest to the semiconductor substrate 102 (i.e., the portion in contact with the metal layer 108a) and the semiconductor substrate 102 is shorter than the distance between the semiconductor substrate 102 and the reflective surface (part of the upper surface) of the reflective layer 108. As described above, by making the resistivity of the material of the metal layer 108a higher than that of the material of the metal layer 108b, the contact resistance between the metal layer 108a and the lower electrode 110 can be reduced. The lower electrode 110 can include a high-transmittance material such as ITO or IZO. In the example of FIG. 1, a portion of the lower electrode 110 is in contact with the metal layer 108b as well. Alternatively, the lower electrode 110 need not be in contact with the metal layer 108b.

An isolation member 111 is disposed on the lower electrode 110. A portion of the isolation member 111 (specifically, the lower surface thereof) is in contact with the lower electrode 110 (specifically, the upper surface thereof). The isolation member 111 covers a part of the lower electrode 110 and does not cover a part of the lower electrode 110. The portion of the lower electrode 110 that is covered by the isolation member 111 includes the portion of the lower electrode 110 that passes through the optical adjustment layer 109. In other words, the isolation member 111 enters a recessed portion of the lower electrode 110. The isolation member 111 may include, for example, SiO. The isolation member 111 may also be called a bank.

An organic layer 112 is disposed on the optical adjustment layer 109, the lower electrode 110, and the isolation member 111. The organic layer 112 (specifically, the lower surface thereof) is in contact with the optical adjustment layer 109 (specifically, part of the upper surface thereof), the lower electrode 110 (specifically, part of the upper surface thereof), and the isolation member 111 (specifically, the upper surface thereof). The organic layer 112 includes at least an organic light-emitting material. The organic layer 112 may further include a charge transport layer, a charge blocking layer, a carrier generation layer, and the like. The lower electrode 110 includes a contact portion that is in contact with the organic layer 112 and a non-contact portion that is isolated from the organic layer 112 by the isolation member 111. At least part of the contact portion of the lower electrode 110 is surrounded by the non-contact portion of the lower electrode 110. This portion of the contact portion is a light emitting region of the light-emitting element 120. Accordingly, the isolation member 111 defines the light emitting region of the light-emitting element 120.

An upper electrode 113 is disposed on top of the organic layer 112. Accordingly, the upper electrode 113 is located above the lower electrode 110. The upper electrode 113 (specifically, the bottom surface thereof) is in contact with the organic layer 112 (specifically, the upper surface thereof). The upper electrode 113 can include a transparent material such that the light emitted by the organic layer 112 can be transmitted therethrough. For example, the upper electrode 113 may be a thin film of gold, platinum, silver, aluminum, chromium, magnesium, or an alloy thereof.

A part of the lower electrode 110, a part of the organic layer 112, and a part of the upper electrode 113 form the light-emitting element 120. Specifically, the light-emitting element 120 is formed by the portion of the lower electrode 110 surrounded by the isolation member 111, the portion of the organic layer 112 that overlaps with this surrounded portion, and the portion of the upper electrode 113 that overlaps with this surrounded portion. The light-emitting element 120 is located above the optical adjustment layer 109. The lower electrode 110 can function as an anode of the light-emitting element 120. For this reason, the lower electrode 110 may also be called an anode electrode. The upper electrode 113 can function as a cathode for the light-emitting element 120. For this reason, the upper electrode 113 may also be called a cathode electrode. The lower electrode 110 is in contact with the reflective layer 108 at a position that does not overlap with the light-emitting element 120 in a plan view of the surface of the semiconductor substrate 102. The portion of the lower electrode 110 surrounded by the isolation member 111 may be flat.

A sealing film 114 is disposed on the upper electrode 113. The sealing film 114 (specifically, the lower surface thereof) is in contact with the upper electrode 113 (specifically, the upper surface thereof). The upper surface of the sealing film 114 is flatter than the lower surface of the sealing film 114. The sealing film 114 may have a function of preventing moisture from entering the semiconductor substrate 102, the organic layer 112, and the upper electrode 113. The sealing film 114 may be a composite film such as a silicon nitride film or an Al₂O₃ film formed by, for example, plasma chemical vapor deposition (CVD) or atomic layer deposition (ALD). The thickness of the sealing film 114 may be 2 μm or more.

Color filters 115r, 115g, and 115b are arranged above top of the sealing film 114. The color filters 115r, 115g, and 115b (specifically, the lower surfaces thereof) are in contact with the sealing film 114 (specifically, the upper surface thereof). The color filter 115r is included in the pixel 101r and selectively transmits red light. The color filter 115g is included in the pixel 101g and selectively transmits green light. The color filter 115b is included in the pixel 101b and selectively transmits blue light.

A microlens 116 is disposed on top of the color filters 115r, 115g, and 115b. The microlens 116 (specifically, the lower surface thereof) is in contact with the color filters 115r, 115g, and 115b (specifically, the upper surfaces thereof). The microlens 116 may have a uniform shape over the entire light-emitting region of the light-emitting element 120, or may have partially different curvatures.

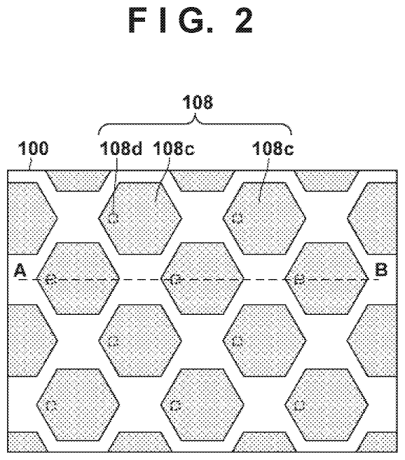

Next, the shape of the reflective layer 108 in a plan view of the surface of the semiconductor substrate 102 will be described with reference to FIG. 2. In FIG. 2, attention is given to only the reflective layer 108. A cross-sectional view taken along line A-B in FIG. 2 can correspond to FIG. 1. The reflective layer 108 is separated into a plurality of portions 108c. One pixel 101 includes one portion 108c. In FIG. 2, only two of the plurality of portions 108c are denoted by reference signs. In the example of FIG. 2, the portions 108c have a hexagonal shape. Alternatively, the portions 108c may have other shapes, such as other polygonal shapes. The plurality of portions 108c may be the same size or may be different sizes. The plurality of portions 108c may have the same shape or different shapes. For example, the portions 108c may have a different size and shape for each light emitting color.

The portions 108c each include a region 108d that is in contact with the lower electrode 110. An opening is formed in the metal layer 108b in the region 108d, and a portion of the lower electrode 110 passes through this opening. In the example of FIG. 2, one portion 108c has only one region 108d. Alternatively, one portion 108c may have a plurality of regions 108d, and a portion of the lower electrode 110 may be in contact with the reflective layer 108 in each of the plurality of regions 108d. The surface area and density of one or more regions 108d in one portion 108c can be set as appropriate.

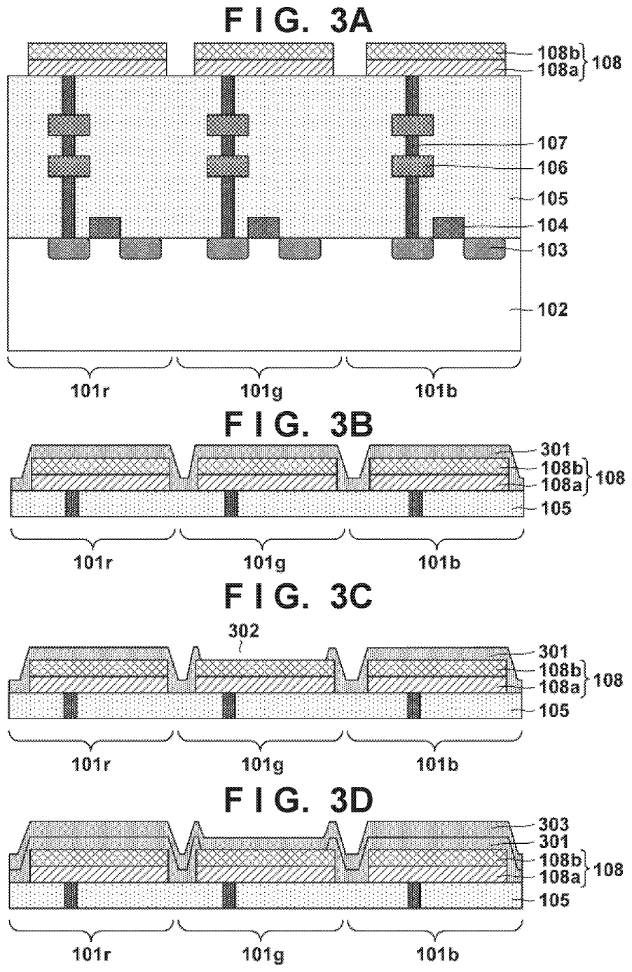

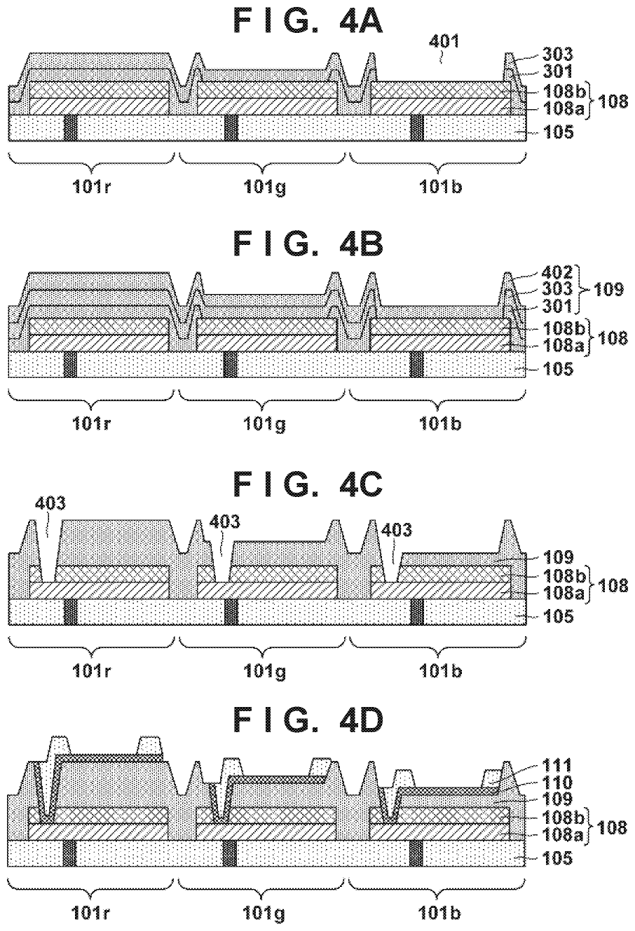

Next, a method for manufacturing the light-emitting device 100 will be described with reference to FIGS. 3A to 4D. First, the wiring layer 106, the contact plugs 107, and the interlayer insulating layer 105 are formed on the semiconductor substrate 102 on which circuit elements have been formed. These constituent elements may be formed using existing technology, and therefore detailed description thereof will be omitted.

Thereafter, the metal layer 108a is formed on the interlayer insulating layer 105 by sputtering. The material of the metal layer 108a may be an above-mentioned material, for example, Ti/TiN. Thereafter, the metal layer 108b is formed on the metal layer 108a by sputtering. The material of the metal layer 108b may be an above-mentioned material, for example, AlCu. The reflective layer 108 is formed by a laminated structure of the metal layer 108a and the metal layer 108b. Thereafter, the reflective layer 108 is subjected to a photolithography step and a dry etching step to divide the reflective layer 108 into the plurality of portions 108c shown in FIG. 2. As a result, the structure of FIG. 3A is formed.

Thereafter, an interference film 301 is formed on the reflective layer 108 by plasma CVD. As a result, the structure of FIG. 3B is formed. In the description of the steps of FIG. 3B and onward, the semiconductor substrate 102 and the lower side of the interlayer insulating layer 105 are omitted. The material of the interference film 301 may be, for example, SiO.

Thereafter, an opening 302 is formed in the interference film 301 so as to expose the upper surface of the portion 108c of the reflective layer 108 that is included in the pixel 101g. As a result, the structure of FIG. 3C is formed. In the pixel 101g, the light-emitting element 120 is formed at the position overlapping with the exposed portion. The opening 302 may be formed by a photolithography step and a dry etching step. The difference between the material of the interference film 301 (e.g., SiO) and the material of the metal layer 108b (e.g., AlCu) allows for a large etching selectivity, and therefore the recess depth of the upper surface of the metal layer 108b can be small.

Thereafter, an interference film 303 is formed on the interference film 301 by plasma CVD. As a result, the structure of FIG. 3D is formed. The material of the interference film 303 may be, for example, SiO. A part of the interference film 303 enters the opening 302.

Thereafter, an opening 401 is formed in the interference films 301 and 303 so as to expose the upper surface of the portion 108c of the reflective layer 108 included in the pixel 101b. As a result, the structure of FIG. 4A is formed. In the pixel 101r, the light-emitting element 120 is formed at a position overlapping with the exposed portion. The opening 401 may be formed by a photolithography step and a dry etching step. The difference between the material of the interference films 301 and 303 (e.g., SiO) and the material of the metal layer 108b (e.g., AlCu) allows for a large etching selectivity, and therefore the recess depth of the upper surface of the metal layer 108b is small.

Thereafter, an interference film 402 is formed on the interference film 303 by plasma CVD. As a result, the structure of FIG. 4B is formed. The material of the interference film 402 may be, for example, SiO. A part of the interference film 402 enters the opening 401. The interference films 301, 303, and 402 form the optical adjustment layer 109.

Thereafter, contact holes 403 that pass through the optical adjustment layer 109 and the metal layer 108b are formed so as to expose parts of the upper surface of the metal layer 108a. As a result, the structure of FIG. 4C is formed. The contact holes 403 may be formed by a photolithography step and a dry etching step.

Thereafter, for example, a conductive film (e.g., an ITO film) is formed on the optical adjustment layer 109 by sputtering. Parts of the conductive film enter the contact holes 403 and come into contact with the metal layer 108a. The lower electrodes 110 are formed by removing unnecessary portions of this conductive film through a photolithography step and dry etching step. Thereafter, an insulating film (e.g., an SiO film) is formed on the lower electrodes 110 by plasma CVD, and unnecessary portions of this conductive film are removed by a photolithography step and a dry etching step, thereby forming the isolation member 111. As a result, the structure of FIG. 4D is formed.

Thereafter, the organic layer 112, the upper electrode 113, the sealing film 114, the color filters 115r, 115g, and 115b, and the microlens 116 are formed in this order, whereby the light-emitting device 100 is manufactured. These constituent elements may be formed using existing technology, and therefore detailed description thereof will be omitted.

When another metal layer is etched using the metal layer 108b as an underlayer, the etching selectivity cannot be increased, and therefore the recess depth of the upper surface of the metal layer 108b increases. This recess can cause a stepped portion on the upper surface of the metal layer 108b. When the organic layer 112 is formed on this stepped portion, a part of the organic layer 112 becomes thin due to the stepped portion, and the electric field between the upper electrode 113 and the lower electrode 110 becomes strong, which can cause leakage current. However, according to the above-described manufacturing method, etching of another metal layer using the metal layer 108b as an underlayer is not performed. For this reason, a stepped portion is less likely to occur in the portion of the reflective layer 108 that functions as a reflective surface. This reduces the occurrence of the above-mentioned leakage current. Furthermore, as shown in FIG. 4C, when the contact holes 403 are formed, the portions of the optical adjustment layer 109 that overlap with the light-emitting elements 120 are covered with a resist, and therefore the thickness of the optical adjustment layer 109 is also maintained. This improves the controllability of the optical adjustment layer 109 in the optical resonance structure.

### Second Embodiment

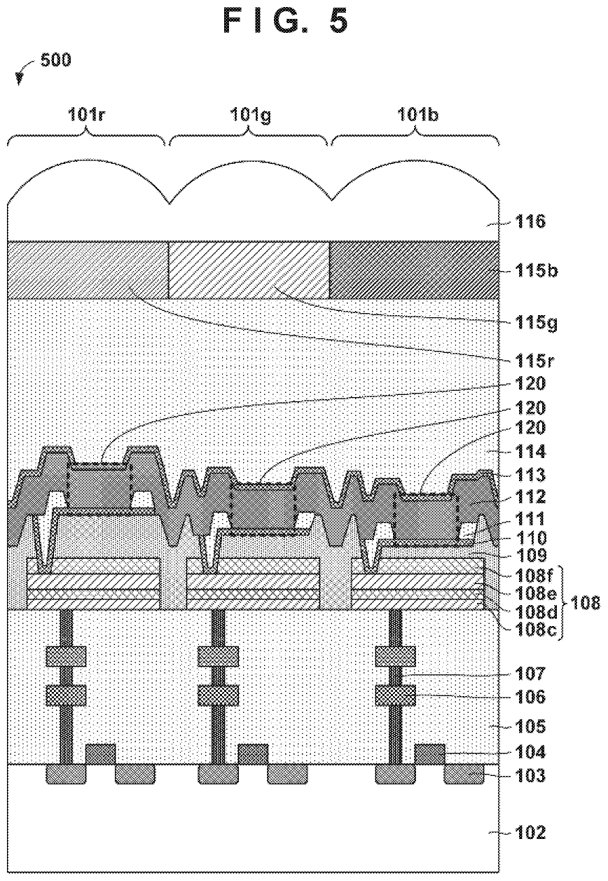

A cross-sectional structure of a light-emitting device 500 according to a second embodiment will be described with reference to FIG. 5. The following mainly describes the differences between the light-emitting device 500 and the light-emitting device 100, and omits redundant description of matters that may be the same as in the light-emitting device 100.

A reflective layer 108 has a laminated structure constituted by a plurality of metal layers laminated on each other. In the example of FIG. 5, the reflective layer 108 has a laminated structure constituted by four metal layers laminated on each other, namely, a metal layer 108c, a metal layer 108d, a metal layer 108e, and a metal layer 108f. The metal layer 108c and the metal layer 108d are in contact with each other. The metal layer 108d is located above the metal layer 108c. The metal layer 108d and the metal layer 108e are in contact with each other. The metal layer 108e is located above top of the metal layer 108d. The metal layer 108e and the metal layer 108f are in contact with each other. The metal layer 108f is located above top of the metal layer 108e. In other words, the metal layer 108e is located below the metal layer 108f.

The metal layer 108c is the lowest layer of the plurality of metal layers. The metal layer 108c includes a portion in contact with an interlayer insulating layer 105 and a portion in contact with a contact plug 107. The metal layer 108f is the uppermost layer of the plurality of metal layers. The upper surface of the metal layer 108f is in contact with the lower surface of the optical adjustment layer 109. The metal layer 108f included in the reflective layer 108 has a reflective surface that reflects light from the light-emitting element 120 toward the light-emitting element 120.

The resistivity of the material of each of the metal layers 108c and 108e may be higher than the resistivity of the material of either of the metal layers 108d and 108f. Accordingly, the contact resistance between the reflective layer 108 and the contact plug 107 can be reduced. The reflectivity of the material of each of the metal layers 108d and 108f may be higher than the reflectivity of the material of either of the metal layers 108c and 108e. As a result, the light emission efficiency of the optical resonance structure formed by the reflective layer 108 can be improved. Each of the metal layers 108c and 108e may include at least one of titanium, titanium nitride, and a titanium alloy. The metal layer 108e may include the same material as the metal layer 108c, or may include a different material. Each of the metal layer 108d and the metal layer 108f may include at least one of aluminum, an aluminum alloy, copper, a copper alloy, silver, and a silver alloy. The metal layer 108d may include the same material as the metal layer 108f, or may include a different material. For example, the metal layer 108f may be a silver alloy and the metal layer 108d may be an aluminum alloy.

The metal layer 108f may be thinner than the metal layer 108d. For example, the thickness of the metal layer 108 f may be about 100 nm. The thickness of the metal layer 108 d may be about 200 nm. By making the metal layer 108 f thinner than the metal layer 108d, the growth of grains on the metal surface can be suppressed, and the reflectivity of the reflective layer 108 can be improved.

The metal layer 108d may be disposed to reduce the resistance of the entire reflective layer 108. For this reason, the metal layer 108d may be thicker than both the metal layer 108c and the metal layer 108e. For example, when the reflective layer 108 also serves as a pad electrode, the wiring routing resistance may be reduced.

In the light-emitting device 500, a portion of the lower electrode 110 passes through the metal layer 108f and is in contact with the upper surface of the metal layer 108e. For this reason, compared to the light-emitting device 100, the distance between the lower end and the upper end of the lower electrode 110 can be reduced, and therefore the resistance between the light-emitting element 120 and the reflective layer 108 can be reduced.

The light-emitting device 500 may be manufactured by laminating four metal layers on the interlayer insulating layer 105 and dividing the four metal layers into a plurality of portions 108c in the step of FIG. 3A.

### Third Embodiment

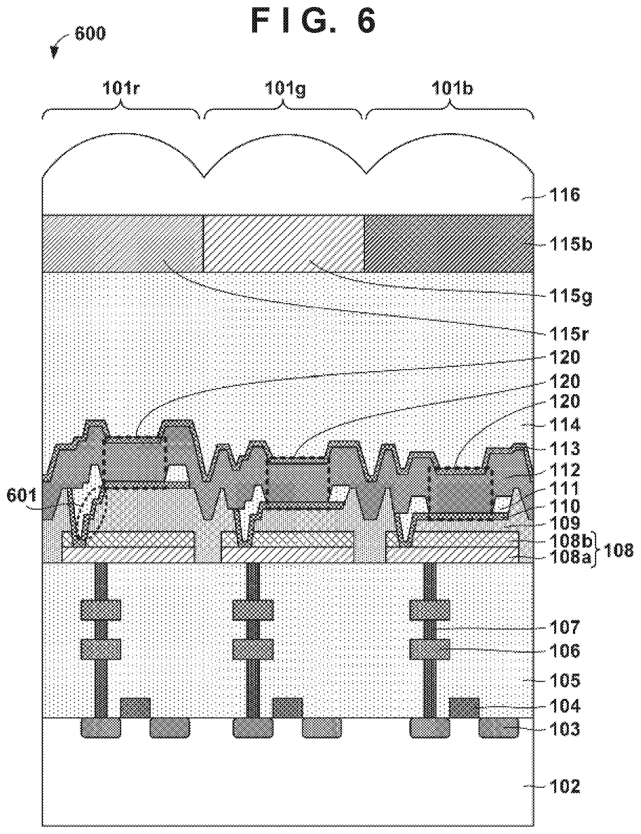

A cross-sectional structure of a light-emitting device 600 according to a third embodiment will be described with reference to FIG. 6. The following mainly describes the differences between the light-emitting device 600 and the light-emitting device 100, and omits redundant description of matters that may be the same as in the light-emitting device 100. This difference may also be applied to the second embodiment.

The lower electrode 110 has a plurality of stepped portions between the portion in contact with the organic layer 112 and the portion in contact with the reflective layer 108 (i.e., a portion 601). As a result, the slope of the portion 601 of the lower electrode 110 is gentler, making it possible to suppress thinning of the portion 601, and thus to suppress an increase in resistance or step disconnection of the portion 601.

One stepped portion in the portion 601 of the lower electrode 110 can be formed by forming the opening 302 in the interference film 301, as well as an opening in the portion where the contact hole 403 of the pixel 101r is to be formed during the step of FIG. 3C. Another stepped portion in the portion 601 of the lower electrode 110 can be formed by forming the opening 401 in the interference films 301 and 303, as well as an opening in the portion where the contact hole 403 of the pixel 101r is to be formed during the step of FIG. 4A.

### Fourth Embodiment

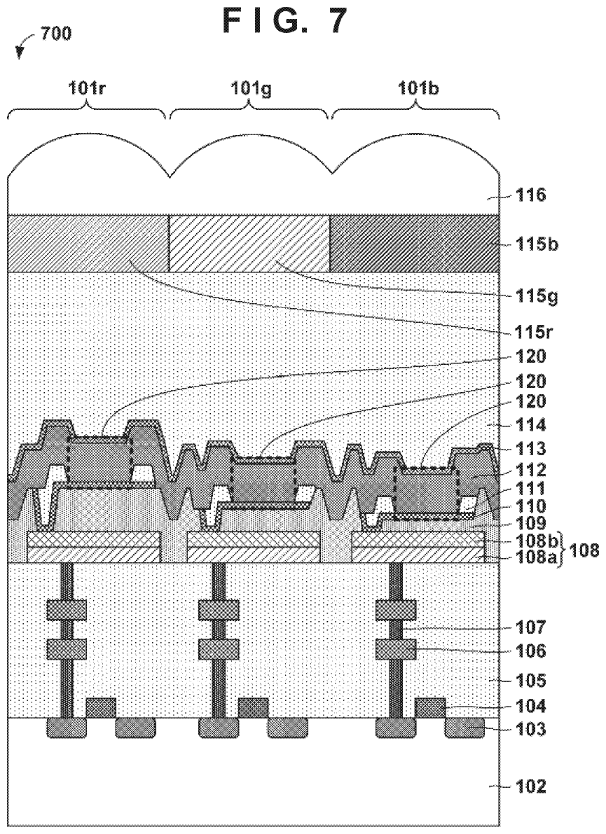

A cross-sectional structure of a light-emitting device 700 according to a fourth embodiment will be described with reference to FIG. 7. The following mainly describes a difference between the light-emitting device 700 and the light-emitting device 100, and omits redundant description of matters that may be the same as in the light-emitting device 100. This difference may also be applied to the second embodiment or the third embodiment.

The lower electrode 110 of the light-emitting device 700 does not pass through the metal layer 108b but is in contact with the upper surface of the metal layer 108b. As a result, the distance between the portion of the lower electrode 110 that is closest to the semiconductor substrate 102 (i.e., the portion in contact with the metal layer 108b) and the semiconductor substrate 102 is the same as the distance between the semiconductor substrate 102 and the reflective surface (part of the upper surface) of the reflective layer 108. As a result, compared to the light-emitting device 100, the distance between the lower end and the upper end of the lower electrode 110 can be reduced, and therefore the resistance between the light-emitting element 120 and the reflective layer 108 can be reduced.

In the light-emitting device 700, the material of the metal layer 108b may be selected such that the difference in work function between the metal layer 108b and the lower electrode 110 is small. This makes it possible to suppress an increase in contact resistance and to stabilize the resistance.

The light-emitting device 700 may be manufactured by forming the contact hole 403 that passes through the optical adjustment layer 109 so as to expose a part of the upper surface of the metal layer 108b in the step of FIG. 4C.

### Fifth Embodiment

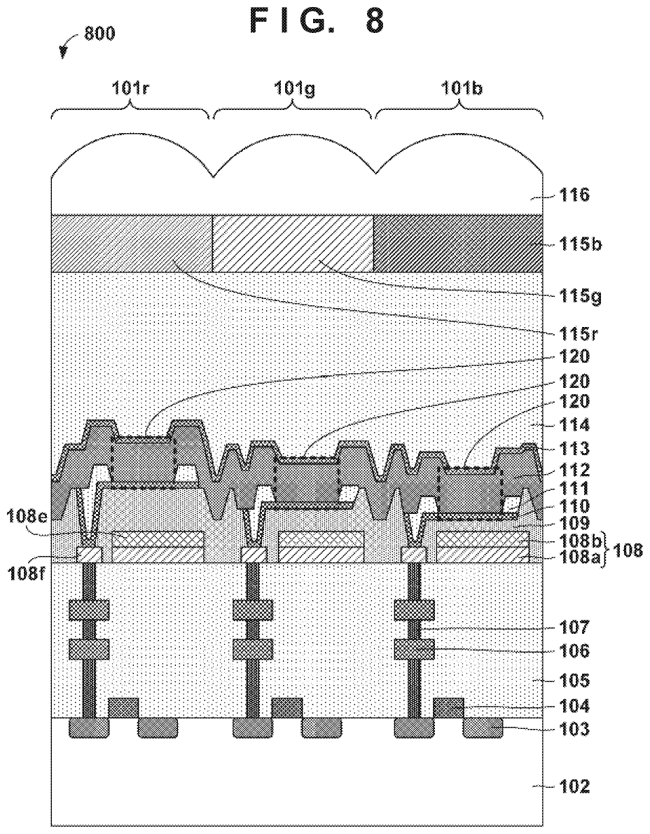

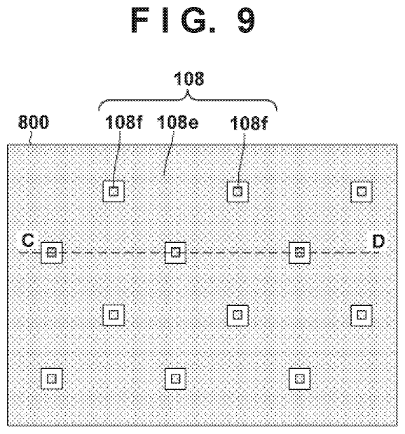

A light-emitting device 800 according to a fifth embodiment will be described with reference to FIGS. 8 and 9. FIG. 8 illustrates a cross-sectional structure of the light-emitting device 800. FIG. 9 illustrates the shape of the reflective layer 108 of the light-emitting device 800 in a plan view of the surface of the semiconductor substrate 102. In FIG. 9, attention is given to only the reflective layer 108. A cross-sectional view taken along line C-D in FIG. 9 can correspond to FIG. 8. The following mainly describes a difference between the light-emitting device 800 and the light-emitting device 100, and omits redundant description of matters that may be the same as in the light-emitting device 100. This difference may also be applied to any of the second to fourth embodiments.

The reflective layer 108 is divided into one portion 108e and a plurality of portions 108f. In FIG. 9, only two of the plurality of portions 108f are denoted by reference signs. The portion 108e is disposed in common for the plurality of pixels 101. The portion 108e (specifically, the upper surface of the metal layer 108b) includes a reflective surface in each pixel 101. One pixel 101 includes one portion 108f. A part of the lower electrode 110 is in contact with the portion 108f (specifically, the lower surface of the metal layer 108a). In addition, a conductive member (e.g., the contact plug 107) embedded in the interlayer insulating layer 105 is in contact with the portion 108f (specifically, the lower surface of the metal layer 108a). In this way, in the light-emitting device 800, the portion of the reflective layer 108 that is in contact with the conductive member (e.g., the contact plug 107) embedded in the interlayer insulating layer 105 is electrically isolated from the reflective surface of the reflective layer 108. This allows the potential of the portion 108e of the reflective layer 108 to be floating. As a result, it is possible to prevent a decrease in the reliability of the organic layer 112 caused by a strong electric field that can occur between the reflective layers 108 of two adjacent pixels 101 of the light-emitting device 800.

In the light-emitting device 800, the portion 108f of the reflective layer 108 does not include the metal layer 108b. For this reason, the lower electrode 110 is not in contact with the metal layer 108b. As a result, a strong electric field that can occur between the reflective layers 108 of two adjacent pixels 101 of the light-emitting device 100 can be suppressed. In addition, the formation of a high-resistance metal oxide film between the metal layer 108b and the lower electrode 110 can be suppressed.

The light-emitting device 800 may be manufactured by removing the metal layer 108b only from the portion 108f of the reflective layer 108 and etching the metal layer 108b so as to leave the metal layer 108b in the portion 108e of the reflective layer 108 in the step of FIG. 4A.

### Sixth Embodiment

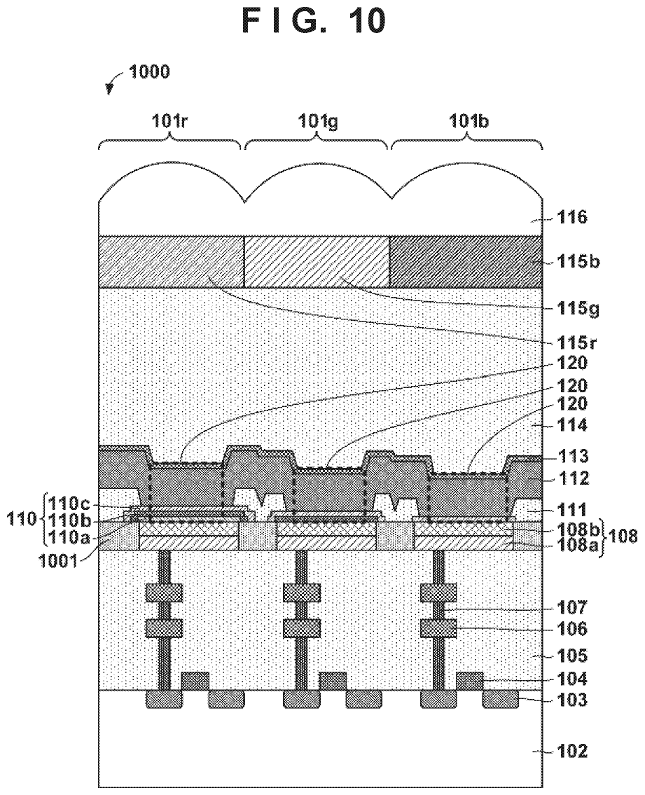

A cross-sectional structure of a light-emitting device 1000 according to a sixth embodiment will be described with reference to FIG. 10. The following mainly describes a difference between the light-emitting device 1000 and the light-emitting device 700 according to the fourth embodiment, and omits redundant description of matters that may be the same as in the light-emitting device 700.

The light-emitting device 1000 does not include the optical adjustment layer 109 between the reflective layer 108 and the lower electrode 110. The lower electrode 110 is in contact with the entire upper surface of the reflective layer 108 (specifically, the upper surface of the metal layer 108b). In particular, the lower electrode 110 is in contact with the metal layer 108b on the side opposite to the portion in contact with the organic layer 112. This allows the surface area of the contact portion to be reduced, and therefore the light-emitting device 1000 can have a larger opening that contributes to light emission than the light-emitting device 700. For this reason, for example, when the light-emitting device 1000 is used as a display device, the viewing angle properties are improved. The metal layer 108a is not in contact with the lower electrode 110.

The lower electrode 110 is a conductive transparent electrode. The thickness of the lower electrode 110 may differ for each pixel 101. For example, the thickness of the lower electrode 110 may be a value corresponding to the resonance wavelength of the corresponding pixel 101. Specifically, the thickness of the portion of the lower electrode 110 included in the pixel 101r may be greater than the thickness of the portion of the lower electrode 110 included in the pixel 101g. The thickness of the portion of the lower electrode 110 included in the pixel 101g may be greater than the thickness of the portion of the lower electrode 110 included in the pixel 101b. As a result, an optical resonance structure is formed in each pixel, and light emission with enhanced brightness is obtained at the resonance wavelength.

An example of a specific structure for realizing the difference in thickness of the lower electrode 110 as described above will be described. The portion of the lower electrode 110 included in the pixel 101r may be constituted by three layers, namely, interference films 110a to 110c. The portion of the lower electrode 110 included in the pixel 101g may be constituted by two layers, namely, the interference films 110b and 110c. The portion of the lower electrode 110 included in the pixel 101b may be constituted by a single layer, namely, the interference film 110c. Out of the interference films 110a to 110c, the interference film 110a is the closest to the semiconductor substrate, and the interference film 110c is the farthest from the semiconductor substrate. The interference film 110b included in each of the pixels 101r and 101g may be generated by separating the same interference film into pixel units. The interference film 110c included in each of the pixels 101r, 101g, and 101b may be generated by separating the same interference film into pixel units. The pixel 101g may include the interference films 110a and 110c instead of the interference films 110b and 110c, or may include the interference films 110a and 110b. The pixel 101b may include the interference film 110a instead of the interference film 110c, or may include the interference film 110b.

Any of the interference films 110a to 110c may be a conductive transparent electrode film. The interference films 110a to 110c include a material such as ITO or IZO. The portions of the reflective layer 108 that are included in two adjacent pixels 101 are isolated from each other by a pixel isolation film 1001. The pixel isolation film 1001 includes an insulating material such as SiO, SiN, or SiON. In addition, similarly to the fourth embodiment, the portions of the lower electrode 110 that are included in two adjacent pixels 101 are isolated from each other by the isolation member 111. The boundary between the pixel isolation film 1001 and the reflective layer 108 is covered by the lower electrode 110.

It is not necessary that all of the interference films 110a to 110c are conductive transparent electrode films, and a part of the interference films 110a to 110c may be a non-conductive insulating film. For example, if the interference film 110c is a conductive transparent electrode film and a part of the interference film 110c is in contact with the reflective layer 108, the interference films 110a and 110b may be non-conductive insulating films. The non-conductive insulating film includes a material such as SiO.

Since the metal layer 108b and the lower electrode 110 are in contact with each other, the materials may be selected such that the difference in work function between the metal layer 108b and the lower electrode 110 is small. This suppresses an increase in contact resistance and stabilizes the resistance. For example, the material of the metal layer 108b may be an alloy of Al containing Ni, an alloy containing Cu, an alloy containing Ag, or any combination thereof. These materials may contain impurities at a ratio of less than 1%.

Next, a method for manufacturing the light-emitting device 1000 will be described. The manufacturing method up to the formation of the reflective layer 108 is the same as that described with reference to FIG. 3A. Thereafter, an insulating film is formed so as to fill the gaps between the island-shaped reflective layers 108. The insulating film may be formed by a combination of different film formation methods such as plasma CVD and high-density plasma CVD. In this way, a film type with favorable step coverage may be applied. Thereafter, the insulating film is planarized by, for example, chemical mechanical polishing (CMP). This eliminates stepped portions between the portion of the insulating film that is on the reflective layer 108 and the portion that covers the gap in the reflective layer 108. At this point, the insulating film includes a portion that is on the reflective layer 108. Thereafter, the portion of the insulating film that is on the reflective layer 108 is removed by dry etching, wet etching, or the like. This exposes the entire upper surface of the reflective layer 108. The remaining portion of the insulating film becomes the pixel isolation film 1001. The upper surface of the pixel isolation film 1001 is recessed below the upper surface of the reflective layer 108. Thereafter, the upper surface of the reflective layer 108 is polished by chemical mechanical polishing (CMP). This eliminates stepped portions caused by crystals and grain boundaries that were formed on the upper surface of the reflective layer 108 when the reflective layer 108 was formed. As a result, the reflectivity of the reflective layer 108 can be improved. For example, by executing CMP under conditions where the polishing rate is high for the reflective layer 108 (e.g., an Al alloy) and the polishing rate is low for the pixel isolation film 1001, the variation in height between the upper surface of the reflective layer 108 and the upper surface of the pixel isolation film 1001 can be reduced.

Thereafter, the material of the interference film 110a is deposited on the entire surface and patterned such that a portion covering the reflective layer 108 of the pixel 101r remains. The remaining portion becomes the interference film 110a. Thereafter, the material of the interference film 110b is deposited on the entire surface and patterned such that portions that cover the reflective layers 108 of the pixels 101r and 101g remain. The remaining portions become the interference film 110b. Thereafter, the material of the interference film 110c is deposited on the entire surface and patterned such that portions that cover the reflective layers 108 of the pixels 101r, 101g, and 101b remain. The remaining portions become the interference film 110c. These patternings may be performed on the upper portion of the pixel isolation film 1001 or may be performed within the region of the reflective layer 108. The manufacturing method for the formation of the isolation member 111 and onward is the same as that described with reference to FIG. 4D.

### Seventh Embodiment

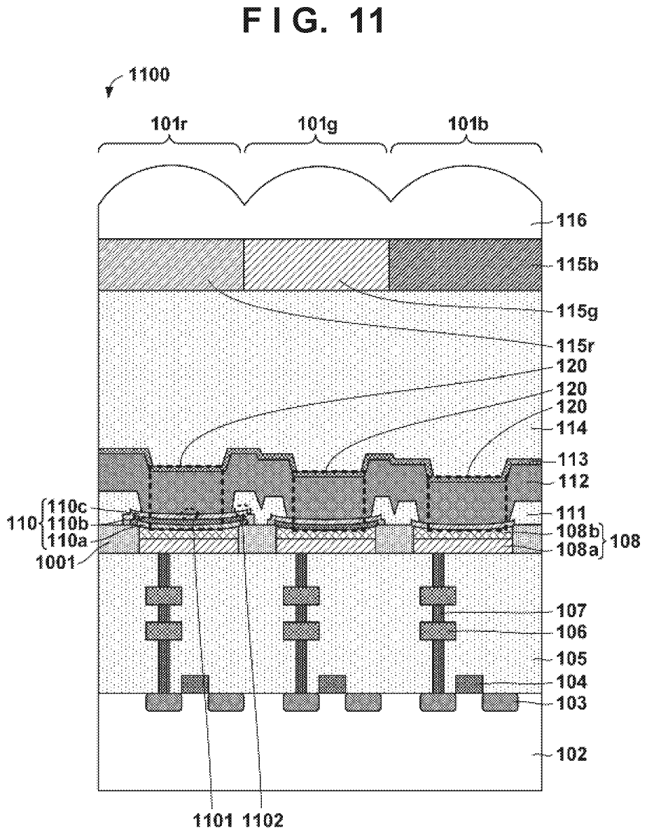

A cross-sectional structure of a light-emitting device 1100 according to a seventh embodiment will be described with reference to FIG. 11. The following mainly describes a difference between the light-emitting device 1100 and the light-emitting device 1000 according to the sixth embodiment, and omits redundant description of matters that may be the same as in the light-emitting device 1000.

The upper surface of the reflective layer 108 (specifically, the upper surface of the metal layer 108b) of the light-emitting device 1100 is recessed toward the semiconductor substrate 102. In other words, the height of a central portion 1101 of the upper surface of the reflective layer 108 is lower than the height of a peripheral portion 1102 of the upper surface of the reflective layer 108, with the semiconductor substrate 102 serving as a reference. The recessed upper surface of the reflective layer 108 allows the light generated in the organic layer 112 to be collected at the light-emitting center of the pixel 101, thereby suppressing light leakage to adjacent pixels. For this reason, for example, when the light-emitting device 1100 is used as a display device, color reproducibility and display efficiency can be improved. In the example of FIG. 11, the upper surface of the reflective layer 108 is a curved surface, but the upper surface of the reflective layer 108 may also include ridges joining surfaces together.

The method for manufacturing the light-emitting device 1100 differs from the method for the light-emitting device 1000 in the conditions for CMP on the upper surface of the reflective layer 108. Specifically, in the method for manufacturing the light-emitting device 1100, an insulating film is formed on the reflective layer 108 and planarized, and then CMP is executed under conditions such that the upper surface of the reflective layer 108 is recessed due to the difference in polishing rate between the insulating film and the reflective layer 108.

### Eighth Embodiment

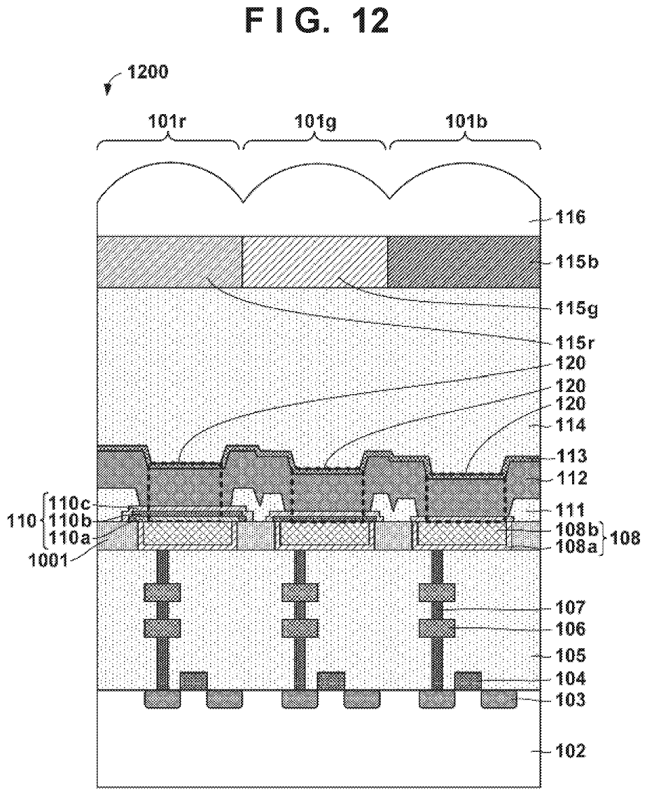

A cross-sectional structure of a light-emitting device 1200 according to the eighth embodiment will be described with reference to FIG. 12. The following mainly describes a difference between the light-emitting device 1200 and the light-emitting device 1000 according to the sixth embodiment, and omits redundant description of matters that may be the same as in the light-emitting device 1000. The difference between the sixth embodiment and the eighth embodiment may also be applied to the seventh embodiment.

The metal layer 108a of the light-emitting device 1200 is in contact with the lower surface and side surfaces of the metal layer 108b. The metal layer 108a includes a portion that is not covered by the metal layer 108b. The metal layer 108a is in contact with the lower electrode 110. Specifically, in the pixel 101r, the metal layer 108a is in contact with the interference film 110a. In the pixel 101g, the metal layer 108a is in contact with the interference film 110b. In the pixel 101b, the metal layer 108a is in contact with the interference film 110c. Due to including a portion where the metal layer 108a is in contact with the lower electrode 110, the materials of the metal layers 108a and 108b can be selected so as to reduce the contact resistance between the reflective layer 108 and the lower electrode 110. For example, the metal layer 108a may include at least one of titanium, titanium nitride, and a titanium alloy. The metal layer 108b may include at least one of aluminum, an aluminum alloy (e.g., including nickel), copper, a copper alloy, silver, and a silver alloy. These materials may contain impurities at a ratio of less than 1%. By reducing the contact resistance between the reflective layer 108 and the lower electrode 110, fluctuations in brightness due to voltage drops in the light-emitting element 120 of the light-emitting device 1200 can be suppressed.

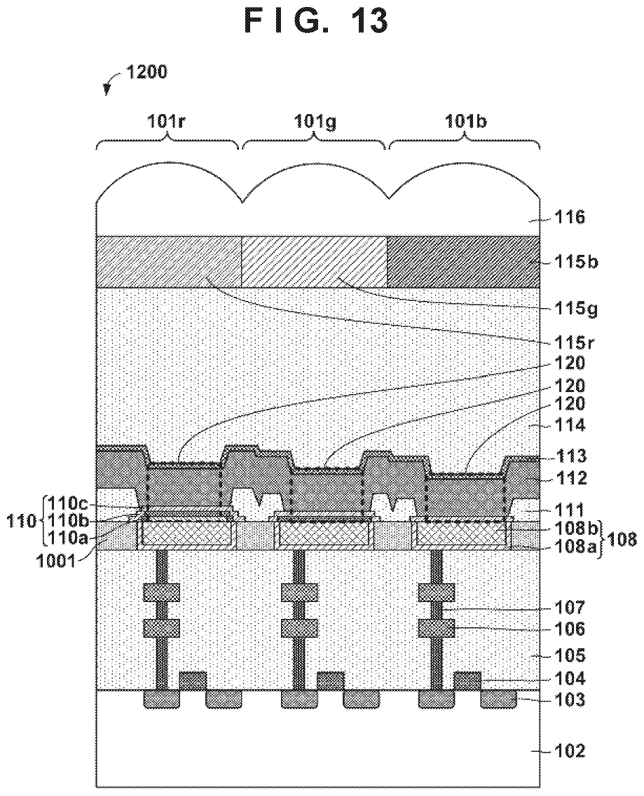

A modified example of the cross-sectional structure of the light-emitting device 1200 according to the eighth embodiment will be described with reference to FIG. 13. In this modification, in each of the pixels 101r, 101g, and 101b, the metal layer 108a is in contact with the interference film 110c. If the material of the lower electrode 110 is ITO or IZO, depending on the manufacturing conditions, the contact resistance is lower when connected to titanium or titanium nitride than when connected to an aluminum alloy, and therefore the contact resistance can be further reduced by using a configuration as in the modified example.

### Ninth Embodiment

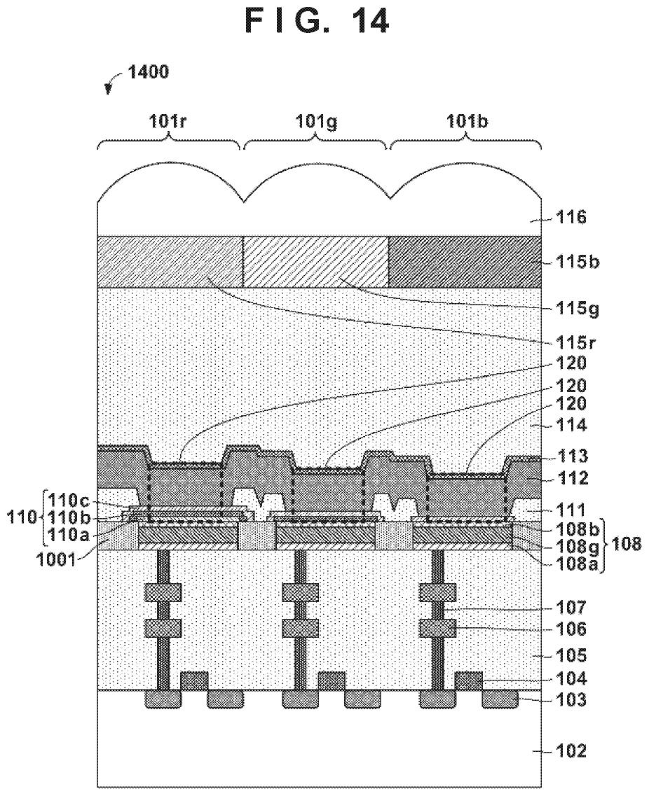

A cross-sectional structure of a light-emitting device 1400 according to a ninth embodiment will be described with reference to FIG. 14. The following mainly describes a difference between the light-emitting device 1400 and the light-emitting device 1000 according to the sixth embodiment, and omits redundant description of matters that may be the same as in the light-emitting device 1000. The difference between the sixth embodiment and the ninth embodiment may also be applied to both the seventh embodiment and the eighth embodiment.

The reflective layer 108 of the light-emitting device 1400 further includes a metal layer 108g between the metal layer 108a and the metal layer 108b. Out of the three metal layers 108a, 108b, and 108g, the metal layer 108a is the closest to the semiconductor substrate 102, and the metal layer 108b is the farthest from the semiconductor substrate 102. The resistivity of the material of the metal layer 108g may be higher than the resistivity of the material of either of the metal layers 108a and 108b. The reflectivity of the material of the metal layer 108g may be higher than the reflectivity of the material of either of the metal layers 108a and 108b. For example, the metal layers 108a and 108b may include at least one of titanium, titanium nitride, and a titanium alloy. The metal layer 108g may include at least one of aluminum, an aluminum alloy (e.g., including nickel), copper, a copper alloy, silver, and a silver alloy. These materials may contain impurities at a ratio of less than 1%.

The metal layer 108b is thinner than both of the metal layers 108a and 108g. For example, the thickness of the metal layer 108 b may be 8 nm or less. Since the metal layer 108b is in contact with the lower electrode 110, the contact resistance between the reflective layer 108 and the lower electrode 110 can be reduced for the same reason as in the eighth embodiment. The metal layer 108b has a larger surface free energy than the metal layer 108g. For this reason, the wettability of the interference film 110a during film formation becomes good, and the flatness of the surface can be improved. The improved flatness suppresses shifting of the resonance wavelength in the optical resonance structure, resulting in light emission with enhanced brightness.

### Tenth Embodiment

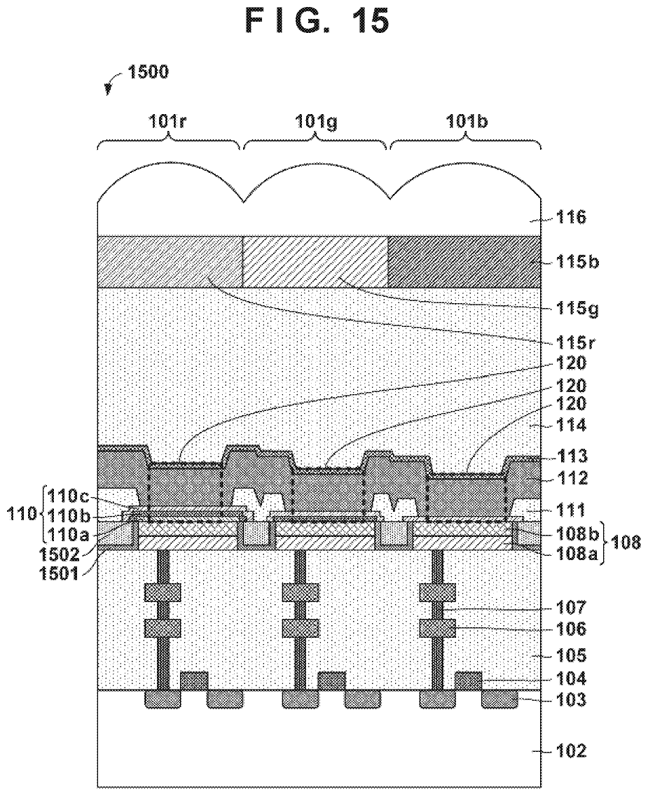

A cross-sectional structure of a light-emitting device 1500 according to a tenth embodiment will be described with reference to FIG. 15. The following mainly describes a difference between the light-emitting device 1500 and the light-emitting device 1000 according to the sixth embodiment, and omits redundant description of matters that may be the same as in the light-emitting device 1000. The difference between the sixth embodiment and the tenth embodiment may also be applied to any of the seventh to ninth embodiments.

In the light-emitting device 1500, the portions of the reflective layer 108 included in two adjacent pixels 101 are insulated from each other by pixel isolation films 1501 and 1502. The material of the pixel isolation films 1501 and 1502 may be SiO, SiN, SiON, or any combination thereof. The pixel isolation film 1501 covers the side surfaces of the reflective layer 108 and the lower surface and side surfaces of the pixel isolation film 1502. The reflective layer 108 and the pixel isolation film 1502 are separated by the pixel isolation film 1501. The interlayer insulating layer 105 and the pixel isolation film 1502 are separated by the pixel isolation film 1501.

Hereinafter, a case will be described in which the pixel isolation film 1501 is a silicon oxide film and the pixel isolation film 1502 is a silicon nitride film. In this case, the selectivity with respect to the underlayer when the interference films 110a to 110c are patterned by dry etching or wet etching becomes large, and a stepped portion of the underlayer caused by excessive etching of the pixel isolation film 1502 can be reduced. As a result, it is possible to suppress thinning at the stepped portion of the underlayer when the organic layer 112 is formed, and thus a leakage current between the lower electrode 110 and the upper electrode 113 can be suppressed. This makes it possible to suppress fluctuations in brightness in a low brightness region of the light-emitting device 1500. Since the material of the pixel isolation film 1501 is SiO, which has a larger band gap than SiN, the leakage current flowing between two portions of the reflective layer 108 that are included in adjacent pixels 101 can be reduced.

### Modified Example of Above Embodiment

In the above-described embodiment, there are three wiring layers from the transistors formed on the semiconductor substrate 102 to the reflective layer 108, but the number of wiring layers is not limited to this. For example, there may be four, five, or more wiring layers. The material of the wiring may be, for example, tungsten, copper, aluminum, or the like. If copper is used as the material of the wiring, a SiC layer may be provided to reduce copper diffusion. The SiC layer may be doped with nitrogen. The wiring layer may also be provided with a capacitance element. The capacitance element has, for example, an MIM structure.

### Configuration of Organic Light-Emitting Element

An organic light-emitting element is provided by forming an insulating layer, a first electrode, an organic compound layer, and a second electrode on a substrate. A protective layer, a color filter, a microlens, and the like may be provided on a cathode. If the color filter is provided, a planarization layer may be provided between the color filter and the protective layer. The planarization layer can be constituted by an acrylic resin or the like. The same applies to the case where a planarization layer is provided between the color filter and the microlens.

### Substrate

The substrate may include quartz, glass, a silicon wafer, a resin, a metal, or the like. In addition, a switching element such as a transistor and wiring may be included on the substrate, and an insulating layer may be included on the switching element and the wiring. Any material can be used for the insulating layer as long as it allows a contact hole to be formed such that wiring can be formed between the insulating layer and the first electrode, and as long as insulation from wiring that is not connected can be ensured. For example, a resin such as polyimide, silicon oxide, silicon nitride, or the like can be used.

### Electrodes

The electrodes may be a pair of electrodes. The pair of electrodes may be an anode and a cathode. When an electric field is applied in the direction in which the organic light-emitting element emits light, the electrode with the higher potential is the anode, and the other is the cathode. In addition, it can also be said that the electrode that supplies holes to the light-emitting layer is the anode, and the electrode that supplies electrons is the cathode.

The constituent material for the anode preferably has as large a work function as possible. For example, a metal such as gold, platinum, silver, copper, nickel, palladium, cobalt, selenium, vanadium, and tungsten, a mixture containing these metals, an alloy combining these metals, and a metal oxide such as tin oxide, zinc oxide, indium oxide, indium tin oxide (ITO), and indium zinc oxide can be used. A conductive polymer such as polyaniline, polypyrrole, and polythiophene can also be used.

For these electrode materials, a single type may be used alone or two or more types may be used in combination. In addition, the anode may be constituted by one layer or a plurality of layers.

When used as a reflective electrode, for example, chromium, aluminum, silver, titanium, tungsten, molybdenum, alloys or laminates thereof, or the like can be used. The above-described materials can also function as a reflective film without acting as an electrode. When used as a transparent electrode, a transparent conductive layer of an oxide such as indium tin oxide (ITO) or indium zinc oxide, or the like can be used, but there is no limitation to these. The electrodes can be formed using photolithography technology.

On the other hand, the cathode preferably includes a material with a small work function. Examples include a simple metal such as an alkali metal such as lithium, an alkaline earth metal such as calcium, aluminum, titanium, manganese, silver, lead, and chromium, and a mixture containing these metals. Alternatively, an alloy combining these simple metals can also be used. For example, magnesium-silver, aluminum-lithium, aluminum-magnesium, silver-copper, zinc-silver, and the like can be used. A metal oxide such as indium tin oxide (ITO) can also be used. These electrode materials may be used alone or in combination of two or more. The cathode may also have either a single layer structure or a multi-layer structure. Among these, silver is preferably used, and a silver alloy is more preferably used in order to reduce aggregation of silver. Any alloy ratio may be used as long as the aggregation of silver can be reduced. For example, the ratio of silver to another metal may be 1:1, 3:1, or the like.

The cathode may be a top-emission element using an oxide conductive layer such as ITO, or a bottom-emission element using a reflective electrode such as aluminum (Al), and is not particularly limited. The method for forming the cathode is not particularly limited, but DC and AC sputtering methods and the like are preferred because they provide favorable film coverage and make it easier to reduce resistance.

### Pixel Isolation Layer

A pixel isolation layer includes a silicon nitride (SiN) film, a silicon oxynitride (SiON) film, or a silicon oxide (SiO) film formed using chemical vapor deposition (CVD). In order to increase the resistance in the in-plane direction of the organic compound layer, it is preferable that the film thickness of the organic compound layer, and particularly the hole transport layer, is thin on the side wall of the pixel isolation layer. Specifically, the film thickness of the side wall can be made thin by increasing the taper angle of the side wall of the pixel isolation layer or the film thickness of the pixel isolation layer and increasing shadowing during vapor deposition.

On the other hand, it is preferable to adjust the taper angle of the side wall of the pixel isolation layer and the film thickness of the pixel isolation layer to such an extent that no voids are formed in the protective layer formed thereon. Since no voids are formed in the protective layer, the occurrence of defects in the protective layer can be reduced. Since the occurrence of defects in the protective layer is reduced, it is possible to reduce deterioration in reliability such as the occurrence of dark spots and poor conduction of the second electrode.

According to this embodiment, even if the taper angle of the side wall of the pixel isolation layer is not steep, it is possible to effectively suppress charge leakage to adjacent pixels. As a result of this study, it was found that the reduction was sufficient as long as the taper angle was in the range of 60 degrees to 90 degrees. The film thickness of the pixel isolation layer is preferably 10 nm or more and 150 nm or less. In addition, the same effect is obtained even if none of the pixel electrodes has a pixel isolation layer. In this case, however, it is preferable to make the film thickness of the pixel electrode half or less of that of the organic layer, or to make the end portion of the pixel electrode forward tapered at less than 60°, since short-circuiting in the organic light-emitting element can be reduced.

### Organic Compound Layer

An organic compound layer may be formed as a single layer or as a plurality of layers. When a plurality of layers are included, they may be called a hole injection layer, a hole transport layer, an electron blocking layer, a light emitting layer, a hole blocking layer, an electron transport layer, and an electron injection layer depending on their functions. The organic compound layer is mainly constituted by an organic compound, but may also contain inorganic atoms and inorganic compounds. For example, it may include copper, lithium, magnesium, aluminum, iridium, platinum, molybdenum, zinc, and the like. The organic compound layer may be disposed between the first electrode and the second electrode, or may be disposed in contact with the first electrode and the second electrode.

If a plurality of light-emitting layers are included, a charge generating portion may be provided between the first light-emitting layer and the second light-emitting layer. The charge generating portion may include an organic compound having a lowest unoccupied molecular orbital energy (LUMO) of −5.0 eV or less. The same applies to the case where a charge generating portion is included between the second light-emitting layer and the third light-emitting layer.

### Protective Layer

A protective layer may be provided on the second electrode. For example, by adhering glass provided with a desiccant onto the second electrode, it is possible to reduce the entry of water or the like into the organic compound layer and reduce the occurrence of display defects. In another embodiment, a passivation film such as silicon nitride may be provided on the cathode to reduce the entry of water or the like into the organic compound layer. For example, after forming the cathode, the cathode may be transported to another chamber without breaking the vacuum, and a silicon nitride film having a thickness of 2 μm may be formed by CVD to serve as a protective layer. After the film formation by CVD, a protective layer may be provided by atomic layer deposition (ALD). The material of the film formed by ALD is not limited, but may be silicon nitride, silicon oxide, aluminum oxide, or the like. Silicon nitride may be further formed by CVD on the film formed by ALD. The film formed by ALD may have a smaller film thickness than the film formed by CVD. Specifically, the film thickness of the film formed by ALD may be 50% or less, or even 10% or less of that of the film formed by CVD.

### Color Filter

A color filter may be provided on the protective layer. For example, a color filter taking into consideration the size of the organic light-emitting element may be provided on a separate substrate and then bonded to the substrate on which the organic light-emitting element is provided, or a color filter may be patterned on the protective layer described above using photolithography technology. The color filter may include a high-molecular-weight compound.

### Planarization Layer

A planarization layer may be provided between the color filter and the protective layer. The planarization layer is provided to reduce unevenness of the underlying layer. It may also be called a material resin layer without limiting its purpose. The planarization layer may include an organic compound, and may be either a low-molecular-weight compound or a high-molecular-weight compound, but is preferably a high-molecular-weight compound.

Planarization layers may be provided above and below the color filter, and may include the same or different constituent materials. Specific examples include polyvinylcarbazole resin, polycarbonate resin, polyester resin, ABS resin, acrylic resin, polyimide resin, phenol resin, epoxy resin, silicone resin, and urea resin.

### Microlens

The organic light-emitting device may have an optical member such as a microlens on the light-emitting side thereof. The microlens can include acrylic resin, epoxy resin, or the like. The microlens may be used to increase the amount of light extracted from the organic light-emitting device and to control the direction of the extracted light. The microlens may have a hemispherical shape. If the microlens has a hemispherical shape, among tangents to the hemisphere, there is a tangent that is parallel to the insulating layer, and the point of contact between that tangent and the hemisphere is the apex of the microlens. The apex of the microlens can be determined in the same manner in any cross-sectional view. That is, among tangents to the semicircle of the microlens in the cross-sectional view, there is a tangent that is parallel to the insulating layer, and the point of contact between this tangent and the semicircle is the apex of the microlens.

It is also possible to define the midpoint of the microlens. In the cross section of the microlens, a line segment is envisioned from a point where a circular arc shape ends to a point where another circular arc shape ends, and the midpoint of this line segment can be called the midpoint of the microlens. The cross section for distinguishing the apex and the midpoint may be a cross section perpendicular to the insulating layer.

The microlens has a first surface having a convex portion and a second surface opposite to the first surface. The second surface is preferably disposed closer to the functional layer than the first surface. In order to achieve such a configuration, it is necessary to form the microlens on the light-emitting device. If the functional layer is an organic layer, it is preferable to avoid a process that results in a high temperature during the manufacturing step. In addition, if the second surface is configured to be closer to the functional layer than the first surface, it is preferable that the glass transition temperatures of all of the organic compounds constituting the organic layer are 100° C. or more, and more preferably 130° C. or more.

### Opposing Substrate

An opposing substrate may be provided on top of the planarization layer. The opposing substrate is called the opposing substrate because it is provided at a position corresponding to the above-mentioned substrate. The constituent material of the opposing substrate may be the same as that of the above-mentioned substrate. When the above-mentioned substrate is defined as the first substrate, the opposing substrate may be the second substrate.

### Organic Layer

The organic compound layer (hole injection layer, hole transport layer, electron blocking layer, light emitting layer, hole blocking layer, electron transport layer, electron injection layer, etc.) constituting the organic light-emitting device according to one embodiment of the present disclosure are formed by the method indicated below.

The organic compound layer constituting the organic light-emitting device according to one embodiment of the present disclosure can be formed by a dry process such as vacuum deposition, ionization deposition, sputtering, and plasma. Instead of the dry process, a wet process can also be used in which the material is dissolved in a suitable solvent and a layer is formed by a known coating method (e.g., spin coating, dipping, casting, LB method, inkjet method, etc.).

Here, when the layer is formed by vacuum deposition, solution coating, or the like, crystallization or the like is unlikely to occur and excellent stability over time is achieved. When forming a film by a coating method, the film can be formed by combining with a suitable binder resin.

Examples of the binder resin include, but are not limited to, polyvinylcarbazole resin, polycarbonate resin, polyester resin, ABS resin, acrylic resin, polyimide resin, phenol resin, epoxy resin, silicone resin, and urea resin.

These binder resins may be used alone as a homopolymer or copolymer, or as a mixture of two or more kinds. A known additive such as a plasticizer, an antioxidant, and an ultraviolet absorber may also be used in combination as needed.

### Pixel Circuit

The light-emitting device may include a pixel circuit connected to a light-emitting element. The pixel circuit may be of an active matrix type that controls the light emission of the first light-emitting element and the second light-emitting element independently. Active matrix circuits may be voltage-programmed or current-programmed. The drive circuit has a pixel circuit for each pixel. The pixel circuit may include a light-emitting element, a transistor that controls the light-emitting brightness of the light-emitting element, a transistor that controls the light-emitting timing, a capacitor that holds the gate voltage of the transistor that controls the light-emitting brightness, and a transistor for connecting to GND without going through the light-emitting element.

The light-emitting device has a display region and a peripheral region disposed around the display region. The display region has a pixel circuit, and the peripheral region has a display control circuit. The mobility of the transistors that constitute the pixel circuit may be smaller than the mobility of the transistors that constitute the display control circuit.

The slope of the current-voltage characteristics of the transistors that constitute the pixel circuit may be smaller than the slope of the current-voltage characteristics of the transistors that constitute the display control circuit. The slope of the current-voltage properties can be measured by the so-called Vg-Ig characteristics.

The transistors that constitute the pixel circuit are transistors connected to a light-emitting element such as the first light-emitting element.

### Pixels

The organic light-emitting device has a plurality of pixels. A pixel has sub-pixels that emit light of different colors from each other. The sub-pixels may respectively have, for example, RGB light emission colors.

A pixel has a region, also called a pixel aperture, that emits light. This region is the same as the first region. The pixel aperture may be 15 μm or less, or 5 μm or more. More specifically, it may be 11 μm, 9.5 μm, 7.4 μm, 6.4 μm, or the like.

The distance between the subpixels may be 10 μm or less, and specifically may be 8 μm, 7.4 μm, or 6.4 μm.

The pixels may be arranged in a known manner in a plan view. For example, it may be a stripe arrangement, a delta arrangement, a pentile arrangement, or a Bayer arrangement. The shape of the sub-pixel in plan view may be any known shape. For example, it may be a rectangle, a quadrangular shape such as a diamond, a hexagon, or the like. Of course, it need not be an exact shape, but it is included in a rectangle as long as it is a shape close to a rectangle. The shape of the sub-pixel and the pixel arrangement can be used in combination.

### Use of Organic Light-Emitting Device According to One Embodiment of the Present Disclosure

The organic light-emitting device according to one embodiment of the present disclosure can be used as a component of a display device or a lighting device. Other applications include an exposure light source for an electrophotographic image forming apparatus, a backlight for a liquid crystal display device, and a light-emitting device having a white light source and a color filter.

The display device may be an image information processing device that has an image input unit that inputs image information from an area CCD, a linear CCD, a memory card, or the like, has an information processing unit that processes the input information, and displays the input image on a display unit.

In addition, the display unit included in an image capture device or inkjet printer may have a touch panel function. The method for driving this touch panel function is not particularly limited and may be an infrared method, a capacitance method, a resistive film method, or an electromagnetic induction method. The display device may also be used as a display unit of a multifunction printer.

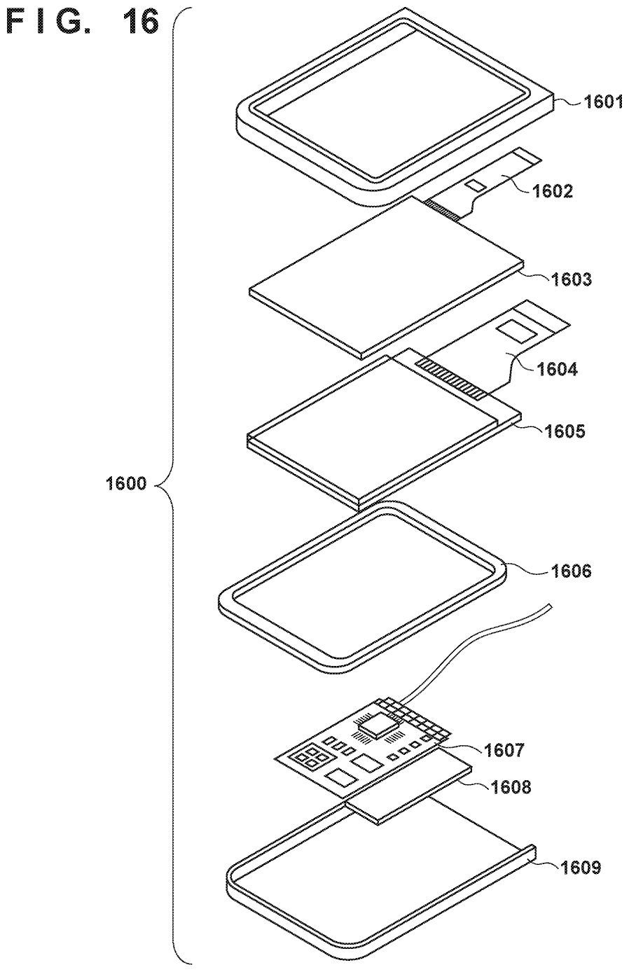

FIG. 16 is a schematic diagram illustrating an example of a display device according to the present embodiment. The display device 1600 may include a touch panel 1603, a display panel 1605, a frame 1606, a circuit board 1607, and a battery 1608 between an upper cover 1601 and a lower cover 1609. The touch panel 1603 and the display panel 1605 are connected to flexible printed circuits FPC 1602 and 1604. The circuit board 1607 has transistors printed on it. The battery 1608 need not be provided if the display device is not a portable device, or may be provided in a different location if the display device is a portable device.

The display device according to this embodiment may have color filters having a red color, a green color, and a blue color. The red, green and blue color filters may be arranged in a delta arrangement.

The display device according to this embodiment may also be used in a display unit of a mobile terminal. In this case, the display device may have both a display function and an operation function. Examples of mobile terminals include mobile phones such as smartphones, tablets, and head-mounted displays.

The display device according to the present embodiment may be used as a display unit of an image capture device having an optical unit with a plurality of lenses and an image sensor that receives light that has passed through the optical unit. The image capture device may have a display unit that displays information acquired by the image sensor. The display unit may also be a display unit that is exposed to the outside of an image capture device, or may be a display unit that is disposed within a finder. The image capture device may be a digital camera or a digital video camera.

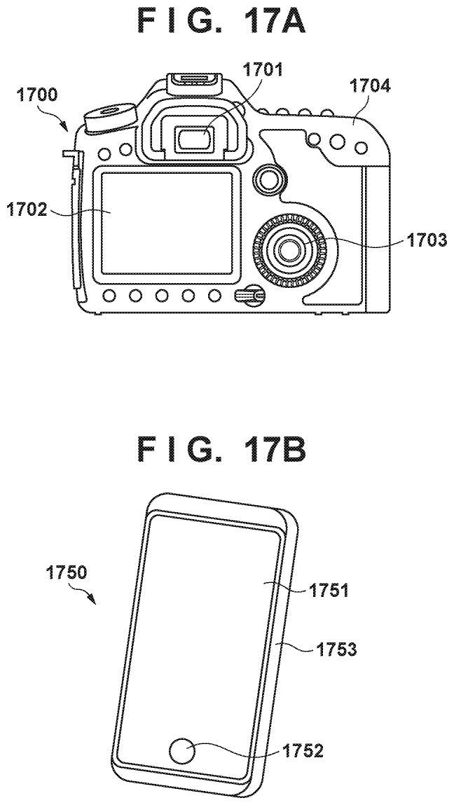

FIG. 17A is a schematic diagram illustrating an example of an image capture device according to the present embodiment. The image capture device 1700 may have a viewfinder 1701, a rear display 1702, an operation unit 1703, and a housing 1704. The viewfinder 1701 may include the display device according to the present embodiment. In this case, the display device may display not only a captured image but also environmental information, an image capture instruction, and the like. The environmental information may include the intensity of external light, the direction of external light, the speed at which a subject moves, the likelihood that the subject will be blocked by an obstruction, and the like.

Since the preferable timing for image capture is a very short amount of time, it is better to display the information as soon as possible. Accordingly, it is preferable to use a display device using the organic light-emitting device of the present disclosure. This is because organic light-emitting elements have a fast response speed. A display device using an organic light-emitting element can be used more preferably than these devices or a liquid crystal display device, which require high display speed.

The image capture device 1700 has an optical unit (not shown). The optical unit has a plurality of lenses and forms an image on an image sensor housed in the housing 1704. The focus of the plurality of lenses can be adjusted by adjusting their relative positions. This operation can also be performed automatically. The image capture device may also be called a photoelectric conversion device. The photoelectric conversion device does not capture images sequentially, but can include an image capturing method such as a method of detecting a difference from a previous image, a method of cutting out an image from a constantly recorded image, or the like.

FIG. 17B is a schematic diagram illustrating an example of an electronic device according to the present embodiment. The electronic device 1750 includes a display unit 1751, an operation unit 1752, and a housing 1753. The housing 1753 may include a circuit, a printed circuit board having the circuit, a battery, and a communication unit. The operation unit 1752 may be a button or a sensing unit of a touch panel system. The operation unit may be a biometric recognition unit that recognizes a fingerprint to perform operations such as unlocking. An electronic device having a communication unit can also be called a communication device. The electronic device may further have a camera function by including a lens and an image sensor. An image captured by the camera function is displayed on the display unit. Examples of electronic devices include smartphones and laptops.

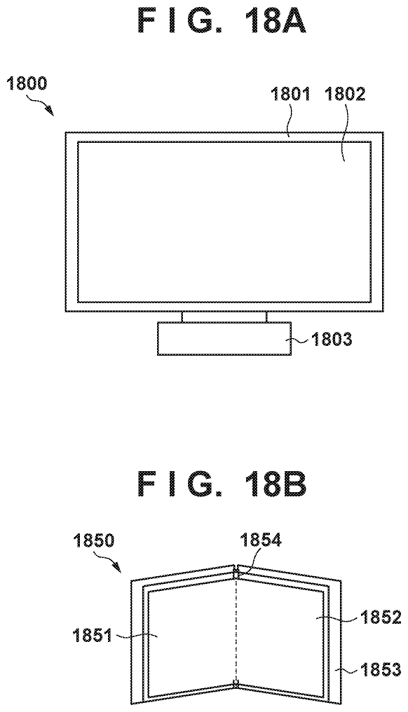

FIGS. 18A and 18B are schematic diagrams illustrating an example of a display device according to the present embodiment. FIG. 18A shows a display device such as a television monitor or a PC monitor. The display device 1800 has a frame 1801 and a display unit 1802. The display unit 1802 may use the light-emitting device according to the present embodiment.

The display device 1800 has a base 1803 that supports the frame 1801 and the display unit 1802. The base 1803 is not limited to the form shown in FIG. 18A. The lower edge of the frame 1801 may also serve as a base.

In addition, the frame 1801 and the display unit 1802 may be curved. The radius of curvature may be 5000 mm or more and 6000 mm or less.

FIG. 18B is a schematic diagram illustrating another example of the display device according to the present embodiment. A display device 1850 in FIG. 18B is configured to be foldable, and is a so-called foldable display device. The display device 1850 includes a first display unit 1851, a second display unit 1852, a housing 1853, and a bending point 1854. The first display unit 1851 and the second display unit 1852 may include the light-emitting device according to the present embodiment. The first display unit 1851 and the second display unit 1852 may be a single seamless display device. The first display unit 1851 and the second display unit 1852 can be divided from each other at a bending point. The first display unit 1851 and the second display unit 1852 may display different images, or the first and second display units may display the same image together.

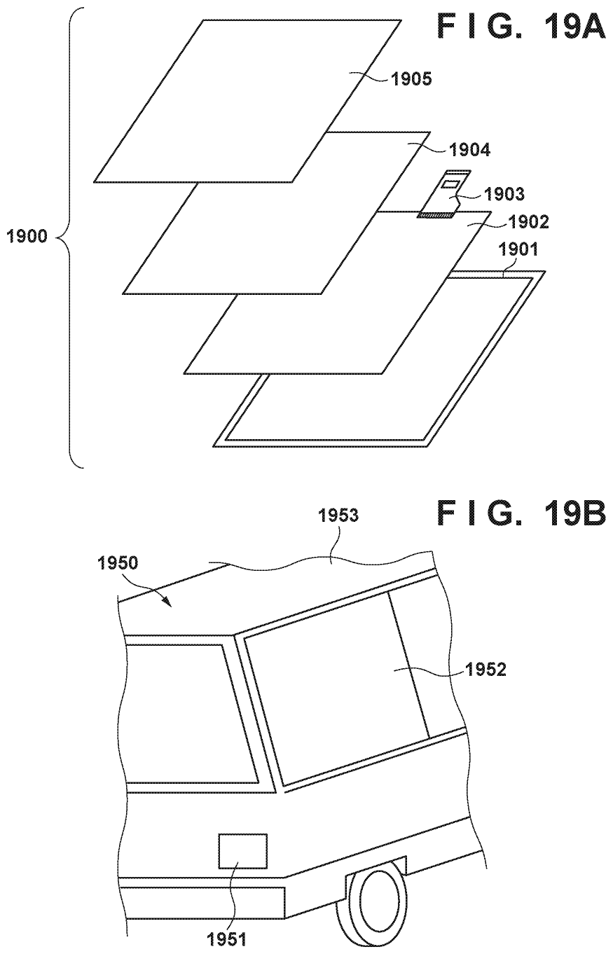

FIG. 19A is a schematic diagram illustrating an example of a lighting device according to the present embodiment. The lighting device 1900 may include a housing 1901, a light source 1902, a circuit board 1903, an optical film 1904, and a light diffusion portion 1905. The light source may include the organic light-emitting device according to the present embodiment. The optical filter may be a filter that improves the color rendering properties of a light source. The light diffusion portion can effectively diffuse light from a light source and deliver the light over a wide range, such as for illumination. The optical filter and the light diffusion portion may be provided on the light emission side of a lighting device. A cover may also be provided on the outermost portion as needed.

The lighting device is, for example, a device that lights up the interior of a room. The lighting device may emit white light, neutral white light, or light of any other color from blue to red. The lighting device may have a dimming circuit for dimming these lights. The lighting device may include the organic light-emitting element of the present disclosure and a power supply circuit connected thereto. The power supply circuit is a circuit that converts AC voltage into DC voltage. Also, white has a color temperature of 4200 K, and neutral white has a color temperature of 5000 K. The lighting device may also have a color filter.

The lighting device according to the present embodiment may also have a heat dissipation portion. The heat dissipation portion dissipates heat from within the device to the outside of the device, and examples of the material include metals with high specific heat, liquid silicon, and the like.

FIG. 19B is a schematic diagram of a vehicle, which is an example of a mobile object according to the present embodiment. The vehicle has tail lamps, which are an example of a lighting fixture. The vehicle 1950 may have tail lamps 1951 that are turned on when a brake operation or the like is performed.

The tail lamps 1951 may include the organic light-emitting element according to the present embodiment. The tail lamps may have a protective member that protects the organic EL element. The protective member may include any material as long as it has a certain degree of strength and is transparent, but it preferably includes polycarbonate or the like. Polycarbonate may be mixed with a furandicarboxylic acid derivative, an acrylonitrile derivative, or the like.

The vehicle 1950 may have a body 1953 and a window 1952 attached thereto. The window may also be a transparent display, as long as it is not a window for viewing the front or rear of the vehicle. The transparent display may include the organic light-emitting device according to the present embodiment. In this case, the constituent materials of the electrodes and the like of the organic light-emitting element are constituted by transparent materials.

The mobile object according to the present embodiment has a driving unit such as an engine or a motor, and moving units such as wheels, a propeller, and tires. For example, the mobile object may be a car, a ship, an airplane, a drone, a bicycle, a railroad vehicle, or the like. The mobile object may have a body and a lighting fixture provided on the body. The lighting fixture may emit light to indicate the position of the body. The lighting fixture has the organic light-emitting element according to the present embodiment.

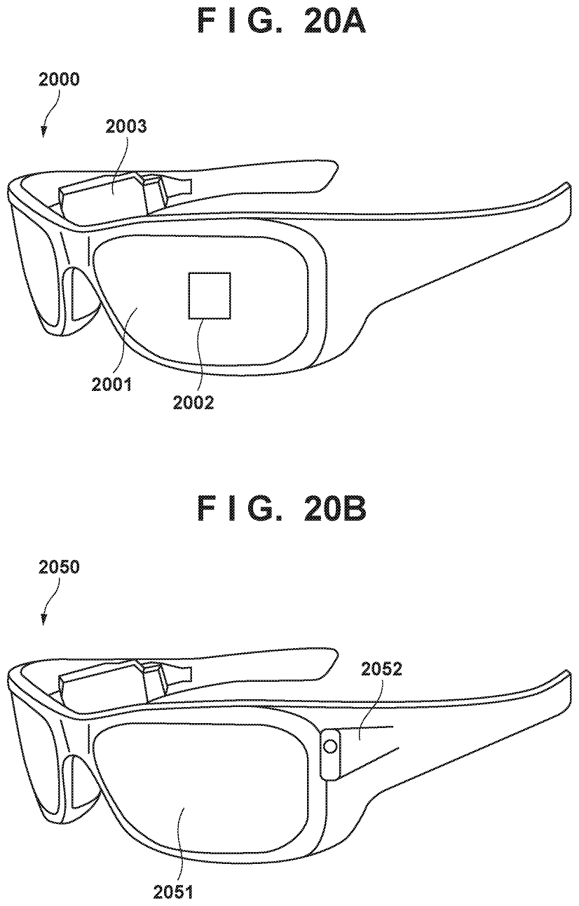

Application examples of the display devices of the above-described embodiments will be described with reference to FIGS. 20A and 20B. The display device can be applied to a system that can be worn as a wearable device, such as smart glasses, an HMD, and smart contacts. An image capture and display device used in such an application example includes an image capture device capable of photoelectrically converting visible light, and a display device capable of emitting visible light.

FIG. 20A illustrates glasses 2000 (smart glasses) according to one application example. An image capture device 2002 such as a CMOS sensor or SPAD is provided on the surface side of a lens 2001 of the glasses 2000. In addition, the display device of each of the above-described embodiments is provided on the rear surface side of the lens 2001.

The glasses 2000 further include a control device 2003. The control device 2003 functions as a power source that supplies power to the image capture device 2002 and the display devices according to the embodiments. In addition, the control device 2003 controls the operation of the image capture device 2002 and the display device. The lens 2001 has an optical system formed therein for focusing light onto the image capture device 2002.

FIG. 20B illustrates glasses 2050 (smart glasses) according to one application example. The glasses 2050 have a control device 2052. The control device 2052 is equipped with an image capture device corresponding to the image capture device 2002 and a display device. An optical system for projecting light emitted by a display device in the control device 2052 is formed in the lens 2051, and an image is projected onto the lens 2051. The control device 2052 functions as a power source that supplies power to the image capture device and the display device, and the control device 2052 controls the operations of the image capture device and the display device. The control device may include a line-of-sight detection unit that detects the line of sight of the wearer. The line of sight may be detected using infrared light. An infrared light emitting unit emits infrared light toward an eyeball of the user gazing at a displayed image. The emitted infrared light is reflected from the eyeball and detected by an image capture unit having a light receiving element, whereby a captured image of the eyeball is obtained. By including a reduction unit that reduces light from the infrared light emitting unit to the display unit in a plan view, degradation of image quality is reduced.

The line of sight of the user with respect to the displayed image is detected from the captured image of the eyeball obtained by image capture using infrared light. Any known method can be applied to detect the line of sight using a captured image of the eyeball. As an example, a line-of-sight detection method based on a Purkinje image obtained by reflection of irradiated light on the cornea can be used.

More specifically, line-of-sight detection processing based on the pupil-corneal reflex method is performed. Using the pupil-corneal reflex method, a line-of-sight vector representing the direction (rotation angle) of the eyeball is calculated based on the pupil image and Purkinje image contained in the captured image of the eyeball, whereby the line of sight of the user is detected.

A display device according to an embodiment of the present disclosure may have an image capture device having a light receiving element, and may control the image displayed on the display device based on information about the line of sight of the user from the image capture device.

Specifically, the display device determines a first display region that the user gazes at and a second display region other than the first display region, based on the line-of-sight information. The first display region and the second display region may be determined by a control device of the display device, or may be determined by an external control device and received. In the display region of the display device, the display resolution of the first display region may be controlled to be higher than the display resolution of the second display region. That is, the resolution of the second display region may be lower than that of the first display region.

In addition, the display region includes a first display region and a second display region different from the first display region, and a region having a higher priority level is determined from the first display region and the second display region based on the line-of-sight information. The first display region and the second display region may be determined by a control device of the display device, or may be determined by an external control device and received. The resolution of the region with the high priority level may be controlled to be higher than the resolution of the region other than the region with the high priority level. That is, the resolution of a region with a relatively low priority level may be lowered.

Note that AI may also be used to determine the first display region and the region with a high priority level. The AI may be a model configured to estimate the angle of the line of sight and the distance to the object in the line of sight from the image of the eyeball, using an image of the eyeball and the direction in which the eyeball in the image was actually looking as training data. An AI program may be included in the display device, the image capture device, or an external device. If the external device has the AI program, the AI program is transmitted to the display device via communication.

If display control is to be performed based on visual recognition detection, the present disclosure can be preferably applied to smart glasses that further include an image capture device that captures an image of the outside. Smart glasses can capture and display external information in real time.

The above-described embodiment provides a reflective layer that achieves both a reflective function and a wiring function.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

1. A light-emitting device comprising:
a substrate;
an interlayer insulating layer that is located above the substrate and has a conductive member embedded therein;
a laminated structure that is located above the interlayer insulating layer and is constituted by a plurality of metal layers laminated on each other; and
a light-emitting element located above the laminated structure, wherein the plurality of metal layers include:
a first metal layer including a portion in contact with the conductive member; and
a second metal layer located above the first metal layer,
the second metal layer has a reflective surface that reflects light from the light-emitting element toward the light-emitting element,
a material of the first metal layer has a resistivity higher than that of a material of the second metal layer, and
the material of the second metal layer has a reflectivity higher than that of the material of the first metal layer.

2. The light-emitting device according to claim 1,
wherein the light-emitting device further comprises a light-transmitting layer between the laminated structure and the light-emitting element.

3. The light-emitting device according to claim 2,
wherein the light-emitting element includes a lower electrode and an upper electrode located above the lower electrode, and
a portion of the lower electrode passes through the light-transmitting layer and is in contact with the laminated structure.

4. The light-emitting device according to claim 3,
wherein a portion of the lower electrode further passes through the second metal layer.

5. The light-emitting device according to claim 4,
wherein a portion of the lower electrode is in contact with the first metal layer.

6. The light-emitting device according to claim 2,
wherein the light-emitting element includes a lower electrode and an upper electrode located above the lower electrode, and
a distance between the substrate and a portion of the lower electrode closest to the substrate is shorter than a distance between the substrate and the reflective surface.

7. The light-emitting device according to claim 1,
wherein the light-emitting element includes a lower electrode and an upper electrode located above the lower electrode, and
a distance between the substrate and a portion of the lower electrode closest to the substrate is the same as a distance between the substrate and the reflective surface.

8. The light-emitting device according to claim 1,
wherein the first metal layer comprises at least one selected from the group consisting of titanium, titanium nitride, and a titanium alloy, and
the second metal layer comprises at least one selected from the group consisting of aluminum, an aluminum alloy, copper, a copper alloy, silver, and a silver alloy.

9. The light-emitting device according to claim 1,
wherein the first metal layer is thinner than the second metal layer.

10. The light-emitting device according to claim 1,
wherein the plurality of metal layers further include:
a third metal layer located above the first metal layer; and
a fourth metal layer located above the third metal layer and below the second metal layer.

11. The light-emitting device according to claim 10,
wherein each of the first metal layer and the fourth metal layer comprises at least one selected from the group consisting of titanium, titanium nitride, and a titanium alloy, and
each of the second metal layer and the third metal layer comprises at least one selected from the group consisting of aluminum, an aluminum alloy, copper, a copper alloy, silver, and a silver alloy.

12. The light-emitting device according to claim 10,
wherein the third metal layer is thicker than the first metal layer and thicker than the fourth metal layer.

13. The light-emitting device according to claim 10,
wherein the second metal layer is thinner than the third metal layer.

14. The light-emitting device according to claim 1, further comprising:
a lower electrode located above the laminated structure;
an organic layer located above the lower electrode; and
an upper electrode located above the organic layer,
wherein the light-emitting element is formed by a portion of the lower electrode, a portion of the organic layer, and a portion of the upper electrode.

15. The light-emitting device according to claim 14,
wherein the lower electrode includes a contact portion in contact with the organic layer and a non-contact portion separated from the organic layer by a separation member.

16. The light-emitting device according to claim 15,
wherein the lower electrode has a plurality of stepped portions between the contact portion and a portion in contact with the laminated structure.

17. The light-emitting device according to claim 1,
wherein the portion of the laminated structure that is in contact with the conductive member is electrically connected to the reflective surface.

18. The light-emitting device according to claim 1,
wherein the portion of the laminated structure that is in contact with the conductive member is electrically separated from the reflective surface.

19. The light-emitting device according to claim 1,
wherein the second metal layer is an uppermost layer of the plurality of metal layers.

20. The light-emitting device according to claim 1, further comprising:
a lower electrode located above the laminated structure;
an organic layer located above the lower electrode; and
an upper electrode located above the organic layer,
wherein the light-emitting element is formed by a portion of the lower electrode, a portion of the organic layer, and a portion of the upper electrode, and
the lower electrode is in contact with the second metal layer on a side opposite to a portion in contact with the organic layer.

21. The light-emitting device according to claim 20,
wherein the first metal layer is not in contact with the lower electrode.

22. The light-emitting device according to claim 20,
wherein an upper surface of the second metal layer is recessed toward the substrate.

23. The light-emitting device according to claim 20,
wherein the first metal layer is in contact with a side surface of the second metal layer and the lower electrode.

24. The light-emitting device according to claim 20,
wherein the plurality of metal layers further include a fifth metal layer between the first metal layer and the second metal layer, and
the second metal layer is thinner than the first metal layer and thinner than the fifth metal layer.

25. The light-emitting device according to claim 20,
wherein the plurality of metal layers further include a fifth metal layer between the first metal layer and the second metal layer,
a material of the fifth metal layer has a resistivity higher than that of each of materials of the first metal layer and the second metal layer, and
the material of the fifth metal layer has a reflectivity higher than that of each of materials of the first metal layer or the second metal layer.

26. The light-emitting device according to claim 20,
wherein the laminated structure is separated into a plurality of portions, and
the light-emitting device further comprises an isolation film that insulates the plurality of portions from each other.

27. The light-emitting device according to claim 26,
wherein the lower electrode covers a boundary between the laminated structure and the isolation film.

28. The light-emitting device according to claim 26,
wherein the isolation film comprises a silicon oxide film and a silicon nitride film that are laminated.

29. A display device comprising:
the light-emitting device according to claim 1; and an element connected to the light-emitting device.

30. A photoelectric conversion device comprising:
an optical unit having a plurality of lenses; an image sensor configured to receive light that passed through the optical unit; and a display unit configured to display an image,
wherein the display unit is a display unit configured to display an image captured by the image sensor, and includes the light-emitting device according to claim 1.

31. An electronic device comprising:
a housing in which a display unit is provided; and a communication unit that is provided in the housing and is configured to communicate with an external device,
wherein the display unit includes the light-emitting device according to claim 1.

32. A lighting device comprising: a light source; and at least one selected from the group consisting of a light diffusion portion and an optical film,
wherein the light source includes the light-emitting device according to claim 1.

33. A mobile object comprising: a body; and a lighting fixture provided on the body,
wherein the lighting fixture includes the light-emitting device according to claim 1.
